(19) United States
(12) Patent Application Publication
(10) Pub. No.: US 2024/0298405 A1
(43) Pub. Date: Sep. 5, 2024

(54) CIRCUIT BOARD WITH ALTERNATE COMPONENT INTEGRATION CAPABILITY

(71) Applicant: Johnson Controls Tyco IP Holdings LLP, Milwaukee, WI (US)

(72) Inventor: Shaun Bradley Atchison, Kansas City, MO (US)

(21) Appl. No.: 18/593,723

(22) Filed: Mar. 1, 2024

Related U.S. Application Data
(60) Provisional application No. 63/449,222, filed on Mar. 1, 2023.

(51) Int. Cl. H05K 1/02; H05K 1/18

(52) U.S. Cl. CPC H05K 1/0298; H05K 1/18; H05K 2201/10984

(57) ABSTRACT

A circuit board includes a first non-conductive layer and a second non-conductive layer. Additionally, the circuit board includes a first electronic component. The circuit board is configurable to operate in a first configuration with a second electronic component, and the circuit board is configurable to operate in a second configuration with a third electronic component instead of the second electronic component. Furthermore, the circuit board includes a first trace layer disposed on the first non-conductive layer. The first trace layer is configured to electrically couple the first electronic component to the second electronic component in a first configuration of the circuit board. Additionally, the circuit board includes a second trace layer disposed between the first non-conductive layer and the second non-conductive layer. The second trace layer is configured to electrically couple the first electronic component to the third electronic component in a second configuration of the circuit board.

### CROSS-REFERENCE TO RELATED APPLICATIONS

This application claims priority from and the benefit of U.S. Provisional Application No. 63/449,222, entitled “CONTROL BOARD WITH ALTERNATE COMPONENT INTEGRATION CAPABILITY,” filed Mar. 1, 2023, which is hereby incorporated by reference in its entirety for all purposes.

### BACKGROUND

This section is intended to introduce the reader to various aspects of art that may be related to various aspects of the present disclosure, which are described below. This discussion is believed to be helpful in providing the reader with background information to facilitate a better understanding of the various aspects of the present disclosure. Accordingly, it should be understood that these statements are to be read in this light, and not as admissions of prior art.

Electronic devices use circuit boards (e.g., printed circuit boards) as a platform for interconnecting electronic components. A circuit board may include conductive pathways (e.g., traces) etched or printed onto a substrate. The arrangement of the conductive pathways on the circuit board may be particularly designed to accommodate a specific set of electronic components. For example, the electronic components may have particular physical geometries (e.g., footprints) and/or electrical configurations (e.g., pinouts) around which the circuit board is designed. Traditionally, changing (e.g., substituting) any of the electronic components in the design of an electronic device demands the fabrication of a new circuit board designed to accommodate a new set of electronic components having a new set of physical geometries and electrical configurations. Such changes and adjustments are costly. Therefore, improved circuit board designs are desired.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, a circuit board includes a first non-conductive layer and a second non-conductive layer. Additionally, the circuit board includes a first electronic component. The circuit board is configurable to operate in a first configuration with a second electronic component, and the circuit board is configurable to operate in a second configuration with a third electronic component instead of the second electronic component. Furthermore, the circuit board includes a first trace layer disposed on the first non-conductive layer. The first trace layer is configured to electrically couple the first electronic component to the second electronic component in a first configuration of the circuit board. Additionally, the circuit board includes a second trace layer disposed between the first non-conductive layer and the second non-conductive layer. The second trace layer is configured to electrically couple the first electronic component to the third electronic component in a second configuration of the circuit board.

In another embodiment, a circuit board includes a microcontroller. The circuit board further includes one of a primary electronic component or a secondary electronic component. Additionally, the circuit board includes a first trace layer formed on a first surface of the circuit board. The first surface includes a primary component footprint corresponding to the primary electronic component. Furthermore, the circuit board includes a second trace layer formed on a second surface of the circuit board, opposite the first surface. The second surface includes a secondary component footprint corresponding to the secondary electronic component. Additionally, the circuit board is configurable to operate in a first configuration associated with installation of the primary electronic component on the primary component footprint. Further, the circuit board is configurable to operate in a second configuration associated with installation of the secondary electronic component on the secondary component footprint.

In another embodiment, a method includes fabricating a printed circuit board (PCB) with a first trace layer disposed on a first surface of the PCB and a second trace layer disposed on a second surface of the PCB. The first surface includes a first component footprint, and the second surface includes a second component footprint. The method further includes mounting an electronic component to the first component footprint without mounting an additional electronic component to the second component footprint. Additionally, the method includes configuring the PCB to operate in a first operating configuration selected from at least two operating configurations, wherein the first operating configuration corresponds to utilization of the first component footprint, and the at least two operating configurations include a second operating configuration corresponding to utilization of the second component footprint.

### BRIEF DESCRIPTION OF THE DRAWINGS

Various aspects of this disclosure may be better understood upon reading the following detailed description and upon reference to the drawings in which:

FIG. 1 is a perspective view of an embodiment of a building that may utilize a building management system (BMS), in accordance with an aspect of the present disclosure;

FIG. 2 is a schematic diagram of an embodiment of a BMS, in accordance with an aspect of the present disclosure;

FIG. 3 is a schematic diagram of a portion of an embodiment of a BMS, in accordance with an aspect of the present disclosure;

FIG. 4 is a schematic diagram of a portion of an embodiment of a BMS, in accordance with an aspect of the present disclosure;

FIG. 5 is a perspective view of an embodiment of a sensor probe that may be utilized with a BMS, in accordance with an aspect of the present disclosure;

FIG. 6 is a schematic diagram of an embodiment of a circuit board in an initial configuration, in accordance with an aspect of the present disclosure;

FIG. 7 is a schematic diagram of an embodiment of the circuit board of FIG. 6 in a first configuration, in accordance with an aspect of the present disclosure;

FIG. 8 is a schematic diagram of an embodiment of the circuit board of FIG. 6 in a second configuration, in accordance with an aspect of the present disclosure;

FIG. 9 is a schematic diagram of an embodiment of the circuit board of FIG. 6 in a third configuration, in accordance with an aspect of the present disclosure;

FIG. 10 is a schematic diagram of an embodiment of a circuit board in a first configuration, in accordance with an aspect of the present disclosure;

FIG. 11 is a schematic diagram of an embodiment of a circuit board in a second configuration, in accordance with an aspect of the present disclosure;

FIG. 12 is a schematic diagram of an embodiment of a voltage divider circuit of a circuit board in a first configuration, in accordance with an aspect of the present disclosure;

FIG. 13 is a schematic diagram of an embodiment of a voltage divider circuit of a circuit board in a second configuration, in accordance with an aspect of the present disclosure;

FIG. 14 is a flowchart of an embodiment of a method of designing a circuit board with alternate component integration capability, in accordance with an aspect of the present disclosure;

FIG. 15 is a flowchart of an embodiment of a method of configuring a circuit board with alternate component integration capability, in accordance with an aspect of the present disclosure; and

FIG. 16 is a flowchart of an embodiment of a method of manufacturing a circuit board with alternate component integration capability, in accordance with an aspect of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

As used herein, the terms “approximately,” “generally,” and “substantially,” and so forth, are intended to convey that the property value being described may be within a relatively small range of the property value, as those of ordinary skill would understand. For example, when a property value is described as being “approximately” equal to (or, for example, “substantially similar” to) a given value, this is intended to mean that the property value may be within +/−5%, within +/−4%, within +/−3%, within +/−2%, within +/−1%, or even closer, of the given value. Similarly, when a given feature is described as being “substantially parallel” to another feature, “generally perpendicular” to another feature, and so forth, this is intended to mean that the given feature is within +/−5%, within +/−4%, within +/−3%, within +/−2%, within +/−1%, or even closer, to having the described nature, such as being parallel to another feature, being perpendicular to another feature, and so forth. Further, it should be understood that mathematical terms, such as “planar,” “slope,” “perpendicular,” “parallel,” and so forth are intended to encompass features of surfaces or elements as understood to one of ordinary skill in the relevant art, and should not be rigidly interpreted as might be understood in the mathematical arts. For example, a “planar” surface is intended to encompass a surface that is machined, molded, or otherwise formed to be substantially flat or smooth (within related tolerances) using techniques and tools available to one of ordinary skill in the art. Similarly, a surface having a “slope” is intended to encompass a surface that is machined, molded, or otherwise formed to be oriented at an angle (e.g., incline) with respect to a point of reference using techniques and tools available to one of ordinary skill in the art.

A circuit board is configured to connect electronic components to one another via conductive pathways (e.g., traces) etched or printed onto a non-conductive substrate of the circuit board. The electronic components may include, for example, an integrated circuit (IC) mounted onto a designated position on the circuit board, such that various pins of the IC establish electrical contact with corresponding conductive elements (e.g., solder pads, holes) of the circuit board. These conductive elements, which may be specifically designed and/or configured to receive a respective electronic component, are herein referred to as a “footprint” corresponding to the electronic component. Each footprint may be designed based on particular physical and/or electrical characteristics of a corresponding electronic component, such as geometric dimensions and pinouts. These characteristics may vary across different embodiments (e.g., makes, manufactures) of functionally similar electronic components. As a result, traditional circuit boards may not be adaptable and/or accommodating with regard to installation of electronic components other than the specific embodiments for which the corresponding footprints of the circuit board were designed. For example, it may be infeasible to substitute unavailable electronic components with alternate electronic components after the circuit board is fabricated.

Accordingly, present embodiments are directed to a circuit board configured to accommodate multiple embodiments (e.g., options) of an electronic component configured to perform a particular function. For example, the circuit board may be configured to accommodate (e.g., support, electrically couple to, integrate with, selectively accommodate) a primary electronic component, as well as accommodate each of one or more alternate electronic component(s) (e.g., secondary electronic components) in lieu of the primary electronic component. Each electronic component embodiment (e.g., option) may have different physical dimensions and/or pinouts relative to other embodiments of the electronic component. Hence, the circuit board may include multiple different footprints corresponding to each electronic component option. Moreover, the electronic component embodiments or options may utilize different control logic and/or communication protocols, which may affect a manner in which a microcontroller interacts with the electronic component. Present embodiments include systems and methods configured to enable a control system (e.g., a circuit board, a microcontroller) to (1) determine which embodiment of an electronic component is installed with a circuit board and (2) adjust operation of a microcontroller of the circuit board accordingly. Advantageously, the circuit board is configured to accommodate (e.g., operate with) each of one or more alternate electronic components without involving the redesigning, rerouting, and retesting the circuit board. Thus, circuit boards and/or control systems utilizing the circuit boards may be manufactured utilizing readily available embodiments of certain electronic components, thereby reducing lead times and costs associating with manufacturing.

In some embodiments, circuit boards incorporating the present techniques may include multiple sets of electronic traces configured to enable incorporation of different embodiments of an electronic component with the circuit board. Different sets of electronic traces supporting the primary and secondary (or alternate) embodiments of electronic components may be routed on different surfaces and/or layers of the circuit board to reduce the overall footprint of the circuit board and to reduce the design complexity of the circuit board. For example, a first trace segment configured for use with a primary electronic component may be routed on a top surface of the circuit board, and a second trace segment configured for use with a secondary electronic component may be routed on a bottom surface of the circuit board. In some embodiments, the circuit board may be a multi-layered printed circuit board (PCB). The electronic components may be connected between layers by vias or through holes extending between the layers.

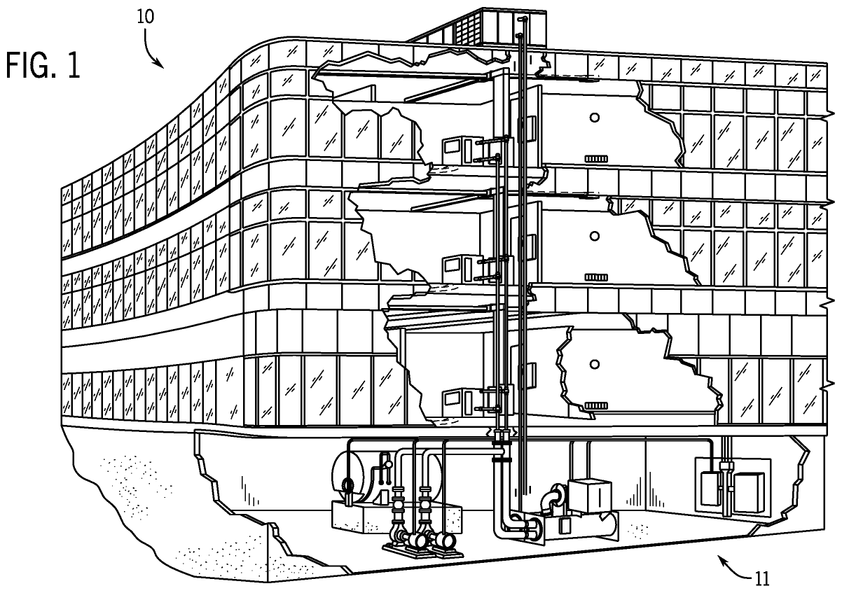

Referring now to FIG. 1, a drawing of a perspective view of an embodiment of a building 10 equipped with a building management system (BMS) 11 is shown, according to aspects of the present disclosure. The BMS 11 serves the building 10. The BMS 11 for the building 10 may include any number or type of devices that serve the building 10. For example, each floor may include one or more security devices, video surveillance cameras, fire detectors, smoke detectors, lighting systems, HVAC systems, or other building systems or devices of the BMS 11. BMS devices can exist on different networks within the building 10 (e.g., one or more wireless networks, one or more wired networks, etc.) and yet serve the same building 10 space or control loop. For example, BMS devices may be connected to different communications networks or field controllers even if the devices serve the same area (e.g., floor, conference room, building zone, tenant area, etc.) or purpose (e.g., security, ventilation, cooling, heating, etc.).

BMS devices may collectively or individually be referred to as building equipment (e.g., of the BMS 11). Building equipment may include any number or type of BMS devices within or around the building 10. For example, building equipment may include controllers, chillers, rooftop units, fire and security systems, elevator systems, thermostats, lighting, serviceable equipment (e.g., vending machines), and/or any other type of equipment that can be used to control, automate, or otherwise contribute to an environment, state, or condition of the building 10. The terms “BMS devices,” “BMS device” and “building equipment” are used interchangeably throughout this disclosure.

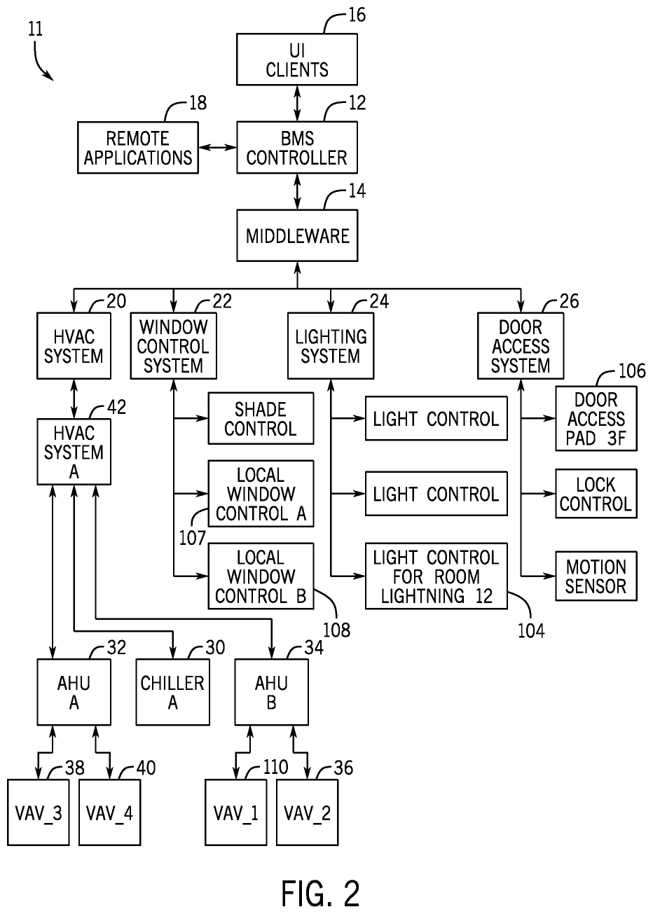

Referring now to FIG. 2, a block diagram of an embodiment of the BMS 11 that serves the building 10 is shown, according to aspects of the present disclosure. The BMS 11 is shown to include a plurality of BMS subsystems 20, 22, 24, and 26. Each BMS subsystem 20-26 is connected to a plurality of BMS devices and makes data points for varying connected devices communicatively coupled to a BMS controller 12. Additionally, the BMS subsystems 20-26 may encompass other lower-level subsystems.

As shown in FIG. 2, the BMS 11 may include an HVAC system 20 as one of the BMS subsystems. The HVAC system 20 may control HVAC operations in the building 10. The HVAC system 20 is shown to include a lower-level HVAC system 42 (e.g., “HVAC system A”). The lower-level HVAC system 42 may control HVAC operations for a specific floor or zone of the building 10. The lower-level HVAC system 42 may be connected to the AHUs 32, 34 (e.g., “AHU A” and “AHU B,” respectively) of the BMS 11. The AHU 32 may serve variable air volume (VAV) boxes 38, 40 (e.g., “VAV_3” and “VAV_4”) of the BMS 11. Likewise, the AHU 34 may serve VAV boxes 36 and 110 (e.g., “VAV_2” and “VAV_1”). The lower-level HVAC system 42 may also include a chiller 30 (e.g., “Chiller A”) of the BMS 11. The chiller 30 may provide chilled fluid to the AHU 32 and/or to the AHU 34. The lower-level HVAC system 42 may receive data (e.g., BMS inputs, such as temperature sensor readings, damper positions, temperature setpoints, etc.) from the AHUs 32, 34. The lower-level HVAC system 42 may provide such BMS inputs to the HVAC system 20, which may be further provided to middleware 14 of the BMS 11, as well as the BMS controller 12. Similarly, other BMS subsystems may receive inputs from other building devices or objects and provide the received inputs to the BMS controller 12 (e.g., via the middleware 14).

The middleware 14 may include services that enable interoperable communication to, from, or between disparate BMS subsystems 20-26 of the BMS 11 (e.g., HVAC systems from different manufacturers, HVAC systems that communicate according to different protocols, security/fire systems, IT resources, door access systems, etc.). While the middleware 14 is shown as separate from the BMS controller 12, the middleware 14 and the BMS controller 12 may be integrated with one another, in some embodiments. That is, the middleware 14 may be a part or component of the BMS controller 12.

Still referring to FIG. 2, a window control system 22 of the BMS subsystems may receive shade control information from one or more shade controls, ambient light level information from one or more light sensors, and/or other BMS inputs (e.g., sensor information, setpoint information, current state information, etc.) from downstream devices. The window control system 22 may include one or more window controllers 107, 108 (e.g., “local window controller A” and “local window controller B,” respectively) of the BMS 11. The window controllers 107, 108 may be configured to control the operation of component subsets of the window control system 22. For example, the window controller 108 may control window blind or shade operations for a given room, floor, or building in the BMS 11.

A lighting system 24 of the BMS subsystems may receive lighting related information from a plurality of downstream light controls (e.g., from room lighting 104). A door access system 26 of the BMS subsystems may receive lock control, motion, state, or other door related information from a plurality of downstream door controls. The door access system 26 is shown to include a door access pad 106 (e.g., “Door Access Pad 3F”), which may grant or deny access to a building space (e.g., a floor, a conference room, an office, etc.) within the building 10 based on whether valid user credentials are scanned or entered (e.g., via a keypad, via a badge-scanning pad, etc.).

The BMS subsystems 20-26 may be connected to the BMS controller 12 via the middleware 14 and may be configured to provide the BMS controller 12 with BMS inputs from the various BMS subsystems 20-26 and their varying downstream devices. The BMS controller 12 may be configured to communicate or convey differences in building subsystems at a human-machine interface or client interface level (e.g., for connected or hosted UI clients 16, remote applications 18, etc.). The BMS controller 12 may be configured to describe or model different building devices and building subsystems using common or unified objects (e.g., software objects stored in memory) to help provide transparency. Software equipment objects may enable developers to write applications capable of monitoring and/or controlling various types of building equipment regardless of equipment-specific variations (e.g., equipment model, equipment manufacturer, equipment version, etc.). Software building objects may enable developers to write applications capable of monitoring and/or controlling building zones on a zone-by-zone level regardless of the building subsystem makeup.

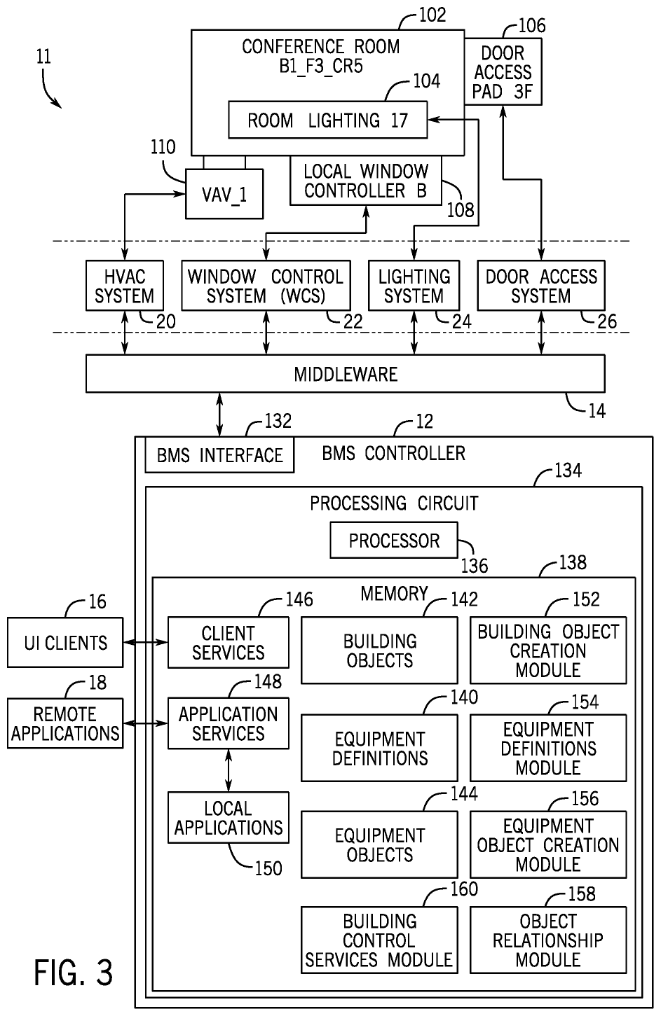

Referring now to FIG. 3, a block diagram illustrating an embodiment of a portion (for example, the BMS controller 12) of the BMS 11 that serves the building 10 in greater detail is shown. Particularly, FIG. 3 illustrates a portion of the BMS 11 that services a conference room 102 of the building 10 (e.g., “B1_F3_CR5”). The conference room 102 may be associated with multiple different building devices connected to multiple different BMS subsystems. For example, the conference room 102 includes or is otherwise associated with the VAV box 110, the window controller 108 (e.g., a blind controller), the room lighting 104 (e.g., “Room Lighting 17”), and an embodiment of the door access pad 106.

Each of the building devices shown in FIG. 3 may include local control circuitry configured to provide signals to their supervisory controllers or more generally to the BMS subsystems 20-26. The local control circuitry of the building devices shown in FIG. 3 may also be configured to receive and respond to control signals, commands, setpoints, or other data from their supervisory controllers. For example, the local control circuitry of the VAV box 110 may include circuitry that controls an actuator in response to control signals received from a field controller that is a part of the HVAC system 20. The window controller 108 may include circuitry that controls windows or blinds in response to control signals received from a field controller that is part of the window control system (WCS) 22. The room lighting 104 may include circuitry that controls the lighting in response to control signals received from a field controller that is part of the lighting system 24. The door access pad 106 may include circuitry that controls door access (e.g., locking or unlocking a door) in response to control signals received from a field controller that is part of the door access system 26.

Still referring to FIG. 3, the BMS controller 12 is shown to include a BMS interface 132 in communication with the middleware 14. In some embodiments, the BMS interface 132 is a communications interface. For example, the BMS interface 132 may include wired or wireless interfaces (e.g., jacks, antennas, transmitters, receivers, transceivers, wire terminals, etc.) configured to conduct data communications with various systems, devices, or networks. The BMS interface 132 can include an Ethernet card and port configured to send and receive data via an Ethernet-based communications network. In another example, the BMS interface 132 includes a Wi-Fi transceiver configured to communicate via a wireless communications network. The BMS interface 132 may be configured to communicate via local area networks or wide area networks (e.g., the Internet, a building WAN, etc.).

In some embodiments, the BMS interface 132 and/or the middleware 14 includes an application gateway configured to receive input from applications running on client devices. For example, the BMS interface 132 and/or the middleware 14 may include one or more wireless transceivers (e.g., a Wi-Fi transceiver, a Bluetooth transceiver, an NFC transceiver, a cellular transceiver, etc.) configured to communicate with client devices. The BMS interface 132 may be configured to receive building management inputs from the middleware 14 or directly from one or more of the BMS subsystems 20-26. The BMS interface 132 and/or the middleware 14 may include any number of software buffers, queues, listeners, filters, translators, or other communications-supporting services.

Still referring to FIG. 3, the BMS controller 12 is shown to include a processing circuit 134 including a processor 136 (e.g., one or more processors, processing circuitry) and a memory 138. The processor 136 may be a general purpose or specific purpose processor, an application specific integrated circuit (ASIC), one or more field programmable gate arrays (FPGAs), a group of processing components, or other suitable processing components. The processor 136 is configured to execute computer code or instructions stored in the memory 138 and/or received from other computer readable media (e.g., CDROM, network storage, a remote server, etc.).

The memory 138 may include one or more devices (e.g., memory units, memory devices, storage devices, etc.) for storing data and/or computer code for completing and/or facilitating the various processes described in the present disclosure. The memory 138 may include random access memory (RAM), read-only memory (ROM), hard drive storage, temporary storage, non-volatile memory, flash memory, optical memory, or any other suitable memory for storing software objects and/or computer instructions. The memory 138 may include database components, object code components, script components, or any other type of information structure for supporting the various activities and information structures described in the present disclosure. The memory 138 may be communicably connected to the processor 136 via the processing circuit 134 and may include computer code for executing (e.g., by the processor 136) one or more processes described herein. When the processor 136 executes instructions stored in the memory 138 for completing the various activities described herein, the processor 136 generally configures the BMS controller 12 (and more particularly the processing circuit 134) to enable completion of such activities.

Still referring to FIG. 3, the memory 138 is shown to include building objects 142. In some embodiments, the BMS controller 12 uses the building objects 142 to group otherwise ungrouped or unassociated devices so that the group may be addressed or handled by applications together and in a consistent manner (e.g., a single user interface for controlling all of the BMS devices that affect a particular building zone or room). The building objects 142 can apply to spaces of any granularity. For example, one of the building objects 142 may represent an entire building, a floor of a building, or individual rooms on each floor. In some embodiments, the BMS controller 12 creates and/or stores one of the building objects 142 in the memory 138 for each zone or room of the building 10. The building objects 142 can be accessed by one or more of the UI clients 16 and/or the remote applications 18 to provide a comprehensive user interface for controlling and/or viewing information for a particular building zone. The building objects 142 may be created by a building object creation module 152 and may be associated with equipment objects by an object relationship module 158, described in greater detail below.

Still referring to FIG. 3, the memory 138 is shown to include equipment definitions 140. The equipment definitions 140 store equipment definitions for various types of building equipment. Each equipment definition 140 may apply to building equipment of a different type. For example, the equipment definitions 140 may include different equipment definitions for variable air volume modular assemblies (VMAs), fan coil units, air handling units (AHUs), lighting fixtures, water pumps, and/or other types of building equipment.

The equipment definitions 140 define the types of data points that are generally associated with various types of building equipment. For example, one of the equipment definitions 140 for a VMA may specify data point types such as room temperature, damper position, supply air flow, and/or other types data measured or used by the VMA. The equipment definitions 140 enable the abstraction (e.g., generalization, normalization, broadening, etc.) of equipment data from a specific BMS device so that the equipment data can be applied to a room or space.

Each of the equipment definitions 140 may include one or more point definitions. Each point definition may define a data point of a particular type and may include search criteria for automatically discovering and/or identifying data points that satisfy the point definition. One or more of the equipment definitions 140 can be applied to multiple pieces of building equipment of the same general type (e.g., multiple different VMA controllers). When one of the equipment definitions 140 is applied to a BMS device, the search criteria specified by the corresponding point definitions can be used to automatically identify data points provided by the BMS device that satisfy each point definition.

In some embodiments, the equipment definitions 140 define data point types as generalized types of data without regard to the model, manufacturer, vendor, or other differences between building equipment of the same general type. The generalized data points defined by the equipment definitions 140 enables each equipment definition 140 to be referenced by or applied to multiple different variants of the same type of building equipment. In some embodiments, the equipment definitions 140 facilitate the presentation of data points in a consistent and user-friendly manner. For example, each equipment definition 140 may define one or more data points that are displayed via a user interface. The displayed data points may be a subset of the data points defined by the equipment definition 140.

In some embodiments, the equipment definitions 140 specify a system type (e.g., HVAC, lighting, security, fire, etc.), a system sub-type (e.g., terminal units, air handlers, central plants), and/or data category (e.g., critical, diagnostic, operational) associated with the building equipment defined by each equipment definition 140. Specifying such attributes of building equipment at the equipment definition level enables the attributes to be applied to the building equipment along with the equipment definition 140 when the building equipment is initially defined. Building equipment can be filtered by various attributes provided in the equipment definition 140 to facilitate the reporting and management of equipment data from multiple building systems. Equipment definitions 140 can be automatically created by abstracting the data points provided by archetypal controllers (e.g., typical or representative controllers) for various types of building equipment. In some embodiments, the equipment definitions 140 are created by an equipment definition module 154, described in greater detail below.

Still referring to FIG. 3, the memory 138 is shown to include equipment objects 144. The equipment objects 144 may be software objects that define a mapping between a data point type (e.g., supply air temperature, room temperature, damper position) and an actual data point (e.g., a measured or calculated value for the corresponding data point type) for various pieces of building equipment. The equipment objects 144 may facilitate the presentation of equipment-specific data points in an intuitive and user-friendly manner by associating each data point with an attribute identifying the corresponding data point type. The mapping provided by the equipment objects 144 may be used to associate a particular data value measured or calculated by the BMS 11 with an attribute that can be displayed via a user interface.

The equipment objects 144 can be created (e.g., by an equipment object creation module 156) by referencing the equipment definitions 140. For example, one of the equipment objects 144 can be created by applying one of the equipment definitions 140 to the data points provided by a BMS device. The search criteria included in the equipment definition 140 can be used to identify data points of the building equipment that satisfy the point definitions. A data point that satisfies a point definition can be mapped to an attribute of the equipment object 144 corresponding to the point definition.

Each equipment object 144 may include one or more attributes defined by the point definitions of the equipment definition 140 used to create the equipment object 144. For example, one of the equipment definitions 140 that defines the attributes “Occupied Command,” “Room Temperature,” and “Damper Position” may result in one of the equipment objects 144 being created with the same attributes. The search criteria provided by the equipment definition 140 are used to identify and map data points associated with a particular BMS device to the attributes of the equipment object 144. The creation of the equipment objects 144 is described in greater detail below with reference to the equipment object creation module 156.

The equipment objects 144 may be related with each other and/or with the building objects 142. Causal relationships can be established between one or more of the equipment objects 144 to link the equipment objects 144 to each other. For example, a causal relationship can be established between a VMA and an AHU which provides airflow to the VMA. Causal relationships can also be established between the equipment objects 144 and the building objects 142. For example, one or more of the equipment objects 144 can be associated with one or more of the building objects 142 representing particular rooms or zones to indicate that the equipment object serves that room or zone. Relationships between objects are described in greater detail below with reference to the object relationship module 158.

Still referring to FIG. 3, the memory 138 is shown to include client services 146 and application services 148. The client services 146 may be configured to facilitate interaction and/or communication between the BMS controller 12 and various internal or external clients or applications. For example, the client services 146 may include web services or application programming interfaces available for communication by user interface (UI) clients 16 and the remote applications 18 (e.g., applications running on a mobile device, energy monitoring applications, applications allowing a user to monitor the performance of the BMS 11, automated fault detection and diagnostics systems, etc.). The application services 148 may facilitate direct or indirect communications between the remote applications 18, local applications 150, and the BMS controller 12. For example, the application services 148 may enable the BMS controller 12 to communicate (e.g., over a communications network) with the remote applications 18 running on mobile devices and/or with other BMS controllers 12.

In some embodiments, the application services 148 facilitate an applications gateway for conducting electronic data communications with the UI clients 16 and/or the remote applications 18. For example, the application services 148 may be configured to receive communications from mobile devices and/or BMS devices. The client services 146 may provide client devices with a graphical user interface that consumes data points and/or display data defined by the equipment definitions 140 and mapped by the equipment objects 144.

Still referring to FIG. 3, the memory 138 is shown to include the building object creation module 152, as mentioned above. The building object creation module 152 may be configured to create the building objects stored in the building objects 142. The building object creation module 152 may create a software building object for various spaces within the building 10. The building object creation module 152 can create one of the building objects 142 for a space of any size or granularity. For example, the building object creation module 152 can create one of the building objects 142 representing an entire building, a floor of a building, or individual rooms on each floor. In some embodiments, the building object creation module 152 creates and/or stores one or more of the building objects 142 in the memory 138 for each zone or room of the building 10.

The building objects 142 created by the building object creation module 152 may be accessed by the UI clients 16 and the remote applications 18 to provide a comprehensive user interface for controlling and/or viewing information for a particular building zone. The building objects 142 can group otherwise ungrouped or unassociated devices so that the group may be addressed or handled by applications together and in a consistent manner (e.g., a single user interface for controlling all of the BMS devices that affect a particular building zone or room). In some embodiments, the building object creation module 152 provides a user interface for guiding a user through a process of creating building objects. For example, the building object creation module 152 may provide a user interface to client devices (e.g., via client services 146) that enables a new space to be defined. In some embodiments, the building object creation module 152 defines spaces hierarchically. For example, the user interface for creating building objects 142 may prompt a user to create a space for a building, for floors within the building, and/or for rooms or zones within each floor.

In some embodiments, the building object creation module 152 creates one or more of the building objects 142 automatically or semi-automatically. For example, the building object creation module 152 may automatically define and create one or more building objects 142 using data imported from another data source (e.g., user view folders, a table, a spreadsheet, etc.). In some embodiments, the building object creation module 152 references an existing hierarchy for the BMS 11 to define the spaces within the building 10. For example, the BMS 11 may provide a listing of controllers for the building 10 (e.g., as part of a network of data points) that have a physical location (e.g., room name) of the controller as the name of the controller. The building object creation module 152 may extract room names from the names of one or more BMS controllers 12 defined in the network of data points and create building objects for each extracted room.

Still referring to FIG. 3, the memory 138 is shown to include an equipment definition module 154. The equipment definition module 154 may be configured to create equipment definitions 140 for various types of building equipment and to store the equipment definitions in the equipment definitions 140. In some embodiments, the equipment definition module 154 may be configured to create one or more equipment definitions 140 by abstracting data points provided by archetypal controllers (e.g., typical or representative controllers) for various types of building equipment. For example, the equipment definition module 154 may receive a user selection of an archetypal controller via a user interface. The archetypal controller may be specified as a user input or selected automatically by the equipment definition module 154. In some embodiments, the equipment definition module 154 may be configured to select an archetypal controller for building equipment associated with a terminal unit such as a VMA.

The equipment definition module 154 may identify one or more data points associated with the archetypal controller. Identifying one or more data points associated with the archetypal controller may include accessing a network of data points provided by the BMS 11. The network of data points may be a hierarchical representation of data points that are measured, calculated, or otherwise obtained by various BMS devices. The BMS devices may be represented in the network of data points as nodes of the hierarchical representation with associated data points depending from each BMS device. The equipment definition module 154 may identify the node corresponding to the archetypal controller in the network of data points and identify one or more data points which depend from the archetypal controller node.

The equipment definition module 154 may generate a point definition for each identified data point of the archetypal controller. Each point definition may include an abstraction of the corresponding data point that is applicable to multiple different controllers for the same type of building equipment. For example, an archetypal controller for a particular VMA (e.g., “VMA-20”) may be associated an equipment-specific data point such as “VMA-20.DPR-POS” (e.g., the damper position of VMA-20) and/or “VMA-20.SUP-FLOW” (e.g., the supply air flow rate through VMA-20). The equipment definition module 154 abstract the equipment-specific data points to generate abstracted data point types that are generally applicable to other equipment of the same type. For example, the equipment definition module 154 may abstract the equipment-specific data point “VMA-20.DPR-POS” to generate the abstracted data point type “DPR-POS” and may abstract the equipment-specific data point “VMA-20.SUP-FLOW” to generate the abstracted data point type “SUP-FLOW.” Advantageously, the abstracted data point types generated by the equipment definition module 154 can be applied to multiple different variants of the same type of building equipment (e.g., VMAs from different manufacturers, VMAs having different models or output data formats, etc.).

In some embodiments, the equipment definition module 154 may be configured to generate a user-friendly label for each point definition. The user-friendly label may be a plain text description of the variable defined by the point definition. For example, the equipment definition module 154 may generate the label “Supply Air Flow” for the point definition corresponding to the abstracted data point type “SUP-FLOW” to indicate that the data point represents a supply air flow rate through the VMA. The labels generated by the equipment definition module 154 may be displayed in conjunction with data values from BMS devices as part of a user-friendly interface.

In some embodiments, the equipment definition module 154 may be configured to generate search criteria for each point definition. The search criteria may include one or more parameters for identifying another data point (e.g., a data point associated with another controller of the BMS 11 for the same type of building equipment) that represents the same variable as the point definition. Search criteria may include, for example, an instance number of the data point, a network address of the data point, and/or a network point type of the data point.

In some embodiments, search criteria include a text string abstracted from a data point associated with the archetypal controller. For example, the equipment definition module 154 may generate the abstracted text string “SUP-FLOW” from the equipment-specific data point “VMA-20.SUP-FLOW.” Advantageously, the abstracted text string matches other equipment-specific data points corresponding to the supply air flow rates of other BMS devices (e.g., “VMA-18.SUP-FLOW,” “SUP-FLOW.VMA-01,” etc.). The equipment definition module 154 may store a name, label, and/or search criteria for each point definition in the memory 138.

The equipment definition module 154 may use the generated point definitions to create an equipment definition for a particular type of building equipment (e.g., the same type of building equipment associated with the archetypal controller). The equipment definition (e.g., equipment definition 140) may include one or more of the generated point definitions. Each point definition defines a potential attribute of BMS devices of the particular type and provides search criteria for identifying the attribute among other data points provided by such BMS devices.

In some embodiments, the equipment definition 140 created by the equipment definition module 154 includes an indication of display data for BMS devices that reference the equipment definition 140. Display data may define one or more data points of the BMS device that will be displayed via a user interface. In some embodiments, display data are user defined. For example, the equipment definition module 154 may prompt a user to select one or more of the point definitions included in the equipment definition 140 to be represented in the display data. Display data may include the user-friendly label (e.g., “Damper Position”) and/or short name (e.g., “DPR-POS”) associated with the selected point definitions.

In some embodiments, the equipment definition module 154 may be configured to provide a visualization of the equipment definition 140 via a graphical user interface. The visualization of the equipment definition 140 may include a point definition portion which displays the generated point definitions, a user input portion configured to receive a user selection of one or more of the point definitions displayed in the point definition portion, and/or a display data portion which includes an indication of an abstracted data point corresponding to each of the point definitions selected via the user input portion. The visualization of the equipment definition 140 may be used to add, remove, or change point definitions and/or display data associated with the equipment definitions 140.

The equipment definition module 154 may generate one or more equipment definitions 140 for each different type of building equipment in the BMS 11 (e.g., VMAs, chillers, AHUs, etc.). The equipment definition module 154 may store the equipment definitions in a data storage device (e.g., the memory 138, the equipment definitions 140, an external or remote data storage device, etc.).

Still referring to FIG. 3, the memory 138 is shown to include an equipment object creation module 156. The equipment object creation module 156 may be configured to create equipment objects 144 for various BMS devices. In some embodiments, the equipment object creation module 156 may be configured to create one of the equipment objects 144 by applying one of the equipment definitions 140 to the data points provided by a BMS device. For example, the equipment object creation module 156 may receive the one of the equipment definitions 140 created by equipment definition module 154. Receiving the equipment definition 140 may include loading or retrieving the equipment definition 140 from a data storage device.

In some embodiments, the equipment object creation module 156 may be configured to determine which of a plurality of equipment definitions 140 to retrieve based on the type of BMS device used to create the equipment object 144. For example, if the BMS device is a VMA, the equipment object creation module 156 may retrieve the equipment definition 140 for VMAs; whereas if the BMS device is a chiller, the equipment object creation module 156 may retrieve the equipment definition 140 for chillers. The type of BMS device to which one of the equipment definitions 140 applies may be stored as an attribute of the equipment definition 140. The equipment object creation module 156 may identify the type of BMS device being used to create the equipment object 144 and retrieve the corresponding equipment definition 140 from the data storage device.

In other embodiments, the equipment object creation module 156 may be configured to receive one of the equipment definition 140 prior to selecting a BMS device. The equipment object creation module 156 may identify a BMS device of the BMS 11 to which the equipment definition 140 applies. For example, the equipment object creation module 156 may identify a BMS device that is of the same type of building equipment as the archetypal BMS device used to generate the equipment definition 140. In various embodiments, the BMS device used to generate the equipment object 144 may be selected automatically (e.g., by the equipment object creation module 156), manually (e.g., by a user) or semi-automatically (e.g., by a user in response to an automated prompt from the equipment object creation module 156).

In some embodiments, the equipment object creation module 156 is configured to create an equipment discovery table based on the equipment definition 140. For example, the equipment object creation module 156 may create an equipment discovery table having attributes (e.g., columns) corresponding to the variables defined by the equipment definition 140 (e.g., a damper position attribute, a supply air flow rate attribute, etc.). Each column of the equipment discovery table may correspond to a point definition of the equipment definition 140. The equipment discovery table may have columns that are categorically defined (e.g., representing defined variables) but not yet mapped to any particular data points.

The equipment object creation module 156 may use the equipment definition 140 to automatically identify one or more data points of the selected BMS device to map to the columns of the equipment discovery table. The equipment object creation module 156 may search for data points of the BMS device that satisfy one or more of the point definitions included in the equipment definition 140. In some embodiments, the equipment object creation module 156 is configured to extract a search criterion from each point definition of the equipment definition 140. The equipment object creation module 156 may access a data point network of the building automation system to identify one or more data points associated with the selected BMS device. The equipment object creation module 156 may use the extracted search criterion to determine which of the identified data points satisfy one or more of the point definitions.

In some embodiments, the equipment object creation module 156 is configured to automatically map (e.g., link, associate, relate, etc.) the identified data points of selected BMS device to the equipment discovery table. A data point of the selected BMS device may be mapped to a column of the equipment discovery table in response to a determination by the equipment object creation module 156 that the data point satisfies the point definition (e.g., the search criteria) used to generate the column. For example, if a data point of the selected BMS device has the name “VMA-18.SUP-FLOW” and a search criterion is the text string “SUP-FLOW,” the equipment object creation module 156 may determine that the search criterion is met. Accordingly, the equipment object creation module 156 may map the data point of the selected BMS device to the corresponding column of the equipment discovery table.

Advantageously, the equipment object creation module 156 may create multiple equipment objects 144 and map data points to attributes of the created equipment objects 144 in an automated fashion (e.g., without human intervention, with minimal human intervention, etc.). The search criteria provided by the equipment definition 140 may facilitate the automatic discovery and identification of data points for a plurality of equipment object 144 attributes. The equipment object creation module 156 may label each attribute of the created equipment objects 144 with a device-independent label derived from the equipment definition 140 used to create the equipment object 144. The equipment objects 144 created by the equipment object creation module 156 may be viewed (e.g., via a user interface) and/or interpreted by data consumers in a consistent and intuitive manner regardless of device-specific differences between BMS devices of the same general type. The equipment objects 144 created by the equipment object creation module 156 may be stored in the equipment objects 144 of the memory 138.

Still referring to FIG. 3, the memory 138 is shown to include an object relationship module 158. The object relationship module 158 may be configured to establish relationships between the equipment objects 144. In some embodiments, the object relationship module 158 establishes causal relationships between the equipment objects 144 based on the ability of one BMS device to affect another BMS device. For example, the object relationship module 158 may establish a causal relationship between a terminal unit (e.g., a VMA) and an upstream unit (e.g., an AHU, a chiller, etc.) which affects an input provided to the terminal unit (e.g., air flow rate, air temperature, etc.).

The object relationship module 158 may establish relationships between the equipment objects 144 and the building objects 142 (e.g., spaces). For example, the object relationship module 158 may associate the equipment objects 144 with the building objects 142 representing particular rooms or zones to indicate that the equipment object 144 serves that room or zone. In some embodiments, the object relationship module 158 provides a user interface through which a user can define relationships between the equipment objects 144 and the building objects 142. For example, a user can assign relationships in a “drag and drop” fashion by dragging and dropping one of the building objects 142 and/or one of the equipment objects 144 into a “serving” cell of the equipment object 144 provided via the user interface to indicate that the BMS device represented by the equipment object 144 serves a particular space or BMS device.

Still referring to FIG. 3, the memory 138 is shown to include a building control services module 160. The building control services module 160 may be configured to automatically control the BMS 11 and the various subsystems thereof. The building control services module 160 may utilize closed loop control, feedback control, PI control, model predictive control, or any other type of automated building control methodology to control the environment (e.g., a variable state or condition) within the building 10.

The building control services module 160 may receive inputs from sensory devices (e.g., temperature sensors, pressure sensors, flow rate sensors, humidity sensors, electric current sensors, cameras, radio frequency sensors, microphones, etc.), user input devices (e.g., computer terminals, client devices, user devices, etc.) or other data input devices via the BMS interface 132. The building control services module 160 may apply the various inputs to a building energy use model and/or a control algorithm to determine an output for one or more building control devices (e.g., dampers, air handling units, chillers, boilers, fans, pumps, etc.) in order to affect a variable state or condition within the building 10 (e.g., zone temperature, humidity, air flow rate, etc.).

In some embodiments, the building control services module 160 is configured to control the environment of the building 10 on a zone-individualized level. For example, the building control services module 160 may control the environment of two or more different building zones of the building 10 using different setpoints, different constraints, different control methodology, and/or different control parameters. The building control services module 160 may operate the BMS 11 to maintain conditions within the building 10 (e.g., temperature, humidity, air quality, etc.) within a setpoint range, to optimize energy performance (e.g., to minimize energy consumption, to minimize energy cost, etc.), and/or to satisfy any constraint or combination of constraints as may be desirable for various implementations.

In some embodiments, the building control services module 160 uses the location of various BMS devices to translate an input received from a building system into an output or control signal for the building system. The building control services module 160 may receive location information for BMS devices and automatically set or recommend control parameters for the BMS devices based on the locations of the BMS devices. For example, the building control services module 160 may automatically set a flow rate setpoint for a VAV box based on the size of the building zone in which the VAV box is located.

The building control services module 160 may determine which of a plurality of sensors to use in conjunction with a feedback control loop based on the locations of the sensors within the building 10. For example, the building control services module 160 may use a signal from a temperature sensor located in a building zone of the building 10 as a feedback signal for controlling the temperature of the building zone in which the temperature sensor is located.

In some embodiments, the building control services module 160 may automatically generate control algorithms for a controller or a building zone based on the location of the zone in the building 10. For example, the building control services module 160 may be configured to predict a change in demand resulting from sunlight entering through windows based on the orientation of the building 10 and the locations of the building zones (e.g., east-facing, west-facing, perimeter zones, interior zones, etc.) within the building 10.

The building control services module 160 may use zone location information and interactions between adjacent building zones (rather than considering each zone as an isolated system) to more efficiently control the temperature and/or airflow within the building 10. For control loops that are conducted at a larger scale (i.e., floor level), the building control services module 160 may use the location of each building zone and/or BMS device to coordinate control functionality between building zones. For example, the building control services module 160 may consider heat exchange and/or air exchange between adjacent building zones as a factor in determining an output control signal for the building zones.

In some embodiments, the building control services module 160 is configured to optimize the energy efficiency of the building 10 using the locations of various BMS devices and the control parameters associated therewith. The building control services module 160 may be configured to achieve control setpoints using building equipment with a relatively lower energy cost (e.g., by causing airflow between connected building zones) in order to reduce the loading on building equipment with a relatively higher energy cost (e.g., chillers and roof top units). For example, the building control services module 160 may be configured to move warmer air from higher elevation zones to lower elevation zones by establishing pressure gradients between connected building zones.

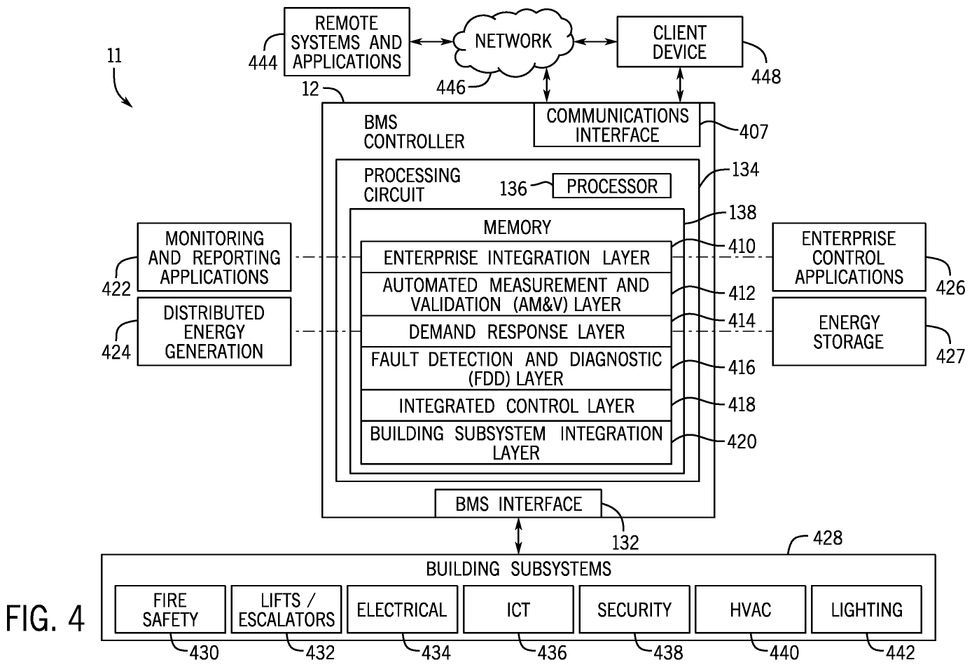

Referring now to FIG. 4, a block diagram illustrating a portion of an embodiment of the BMS 11 configured to serve the building 10 is shown in greater detail. The BMS 11 may be implemented in the building 10, for example, to automatically monitor and control various functions of and/or within the building 10. The BMS 11 is shown to include the BMS controller 12 and a plurality of building subsystems 428. The building subsystems 428 may include a building electrical subsystem 434, an information communication technology (ICT) subsystem 436, a security subsystem 438, an HVAC subsystem 440, a lighting subsystem 442, a lift/escalators subsystem 432, and a fire safety subsystem 430. In various embodiments, the building subsystems 428 can include fewer, additional, or alternative subsystems. For example, the building subsystems 428 may also or alternatively include a refrigeration subsystem, an advertising or signage subsystem, a cooking subsystem, a vending subsystem, a printer or copy service subsystem, or any other type of building subsystem that uses controllable equipment and/or sensors to monitor or control functions, operations, and/or other aspects of or within the building 10.

Each of the building subsystems 428 may include any suitable number of devices, controllers, and connections for completing the individual functions and control activities of the respective building subsystem 428. For example, the HVAC subsystem 440 can include many of the same components as the HVAC system 20 described above. The HVAC subsystem 440 may include a chiller, a boiler, any number of air handling units, economizers, field controllers, supervisory controllers, actuators, temperature sensors, and other devices for controlling the temperature, humidity, airflow, or other variable conditions within the building 10. The lighting subsystem 442 may include any skiable number of light fixtures, ballasts, lighting sensors, dimmers, and/or other devices configured to controllably adjust the amount of light provided to a building space. The security subsystem 438 may include occupancy sensors, video surveillance cameras, digital video recorders, video processing servers, intrusion detection devices, access control devices and servers, or other security-related devices.

Still referring to FIG. 4, the BMS controller 12 may include a communications interface 407 and the BMS interface 132. The communications interface 407 may facilitate communications between the BMS controller 12 and external applications (e.g., monitoring and reporting applications 422, enterprise control applications 426, remote systems and applications 444, applications residing on client devices 448, etc.) to enable user control, monitoring, and adjustment to the BMS controller 12 and/or the building subsystems 428. The communications interface 407 may also facilitate communications between the BMS controller 12 and the client devices 448. The BMS interface 132 may facilitate communications between the BMS controller 12 and the building subsystems 428 (e.g., HVAC systems, lighting security, lifts, power distribution, business, etc.).

The communications interface 407 and/or the BMS interface 132 may be or include wired or wireless communications interfaces (e.g., jacks, antennas, transmitters, receivers, transceivers, wire terminals, etc.) for conducting data communications with the building subsystems 428 or other external systems or devices. In various embodiments, communications via the communications interface 407 and/or the BMS interface 132 may be direct (e.g., local wired or wireless communications) or via a communications network 446 (e.g., a WAN, the Internet, a cellular network, etc.). For example, the communications interface 407 and/or the BMS interface 132 may include an Ethernet card and port for sending and receiving data via an Ethernet-based communications link or network. In another example, the communications interface 407 and/or the BMS interface 132 may include a Wi-Fi transceiver for communicating via a wireless communications network. In another example, one or both of the communications interface 407 and the BMS interface 132 may include cellular or mobile phone communications transceivers. In one embodiment, the communications interface 407 is a power line communications interface, and the BMS interface 132 is an Ethernet interface. In other embodiments, both the communications interface 407 and the BMS interface 132 may be Ethernet interfaces or may include the same Ethernet interface.

Still referring to FIG. 4, the BMS controller 12 is shown to include an embodiment of the processing circuit 134 including the processor 136 (e.g., processing circuitry) and the memory 138. The processing circuit 134 may be communicatively connected to the BMS interface 132 and/or the communications interface 407 such that the processing circuit 134 and the various components thereof are configured to send and receive data via the communications interface 407 and the BMS interface 132. The processor 136 may be implemented as a general purpose processor, an application specific integrated circuit (ASIC), one or more field programmable gate arrays (FPGAs), a group of processing components, or other suitable electronic processing components.

The memory 138 (e.g., memory, memory unit, storage device, etc.) may include one or more devices (e.g., RAM, ROM, Flash memory, hard disk storage, etc.) configured to store data and/or computer code for completing or facilitating the various processes, layers and modules described in the present application. The memory 138 may be or include volatile memory or non-volatile memory. The memory 138 may include database components, object code components, script components, or any other type of information structure for supporting the various activities and information structures described in the present application. According to some embodiments, the memory 138 is communicatively connected to the processor 136 via the processing circuit 134 and includes computer code for executing (e.g., by the processing circuit 134 and/or the processor 136) one or more processes described herein.

In some embodiments, the BMS controller 12 is implemented within a single computer (e.g., one server, one housing, etc.). In various other embodiments, the BMS controller 12 may be distributed across multiple servers or computers (e.g., which may exist in distributed locations). Further, while FIG. 4 shows the monitoring and reporting applications 422 and the enterprise control applications 426 as existing outside of the BMS controller 12, in some embodiments, the monitoring and reporting applications 422 and/or enterprise control applications 426 may be hosted within the BMS controller 12 (e.g., within the memory 138).

Still referring to FIG. 4, the memory 138 is shown to include an enterprise integration layer 410, an automated measurement and validation (AM&V) layer 412, a demand response (DR) layer 414, the FDD layer 416, an integrated control layer 418, and a building subsystem integration layer 420. The layers 410-420 may be configured to receive inputs from the building subsystems 428 and other data sources, determine optimal control actions for the building subsystems 428 based on the inputs, generate control signals based on the optimal control actions, and provide the generated control signals to the building subsystems 428. The following paragraphs describe some of the general functions performed by each of the layers 410-420 in the BMS 11.

The enterprise integration layer 410 may be configured to serve clients or local applications with information and services to support a variety of enterprise-level applications. For example, the enterprise control applications 426 may be configured to provide subsystem-spanning control to a graphical user interface (GUI) or to any number of enterprise-level business applications (e.g., accounting systems, user identification systems, etc.). The enterprise control applications 426 may also or alternatively be configured to provide configuration GUIs for configuring the BMS controller 12. In yet other embodiments, the enterprise control applications 426 can work with the layers 410-420 to optimize building performance (e.g., efficiency, energy use, comfort, or safety) based on inputs received at the communications interface 407 and/or the BMS interface 132.

The building subsystem integration layer 420 may be configured to manage communications between the BMS controller 12 and the building subsystems 428. For example, the building subsystem integration layer 420 may receive sensor data and input signals from the building subsystems 428 and provide output data and control signals to the building subsystems 428. The building subsystem integration layer 420 may also be configured to manage communications between the building subsystems 428. The building subsystem integration layer 420 translate communications (e.g., sensor data, input signals, output signals, etc.) across a plurality of multi-vendor/multi-protocol systems.

The demand response layer 414 may be configured to improve and/or enhance resource usage (e.g., electricity use, natural gas use, water use, etc.) and/or the monetary cost of such resource usage in response to satisfy the demand of the building 10. Such enhancements and/or improvements may be based on time-of-use prices, curtailment signals, energy availability, and/or other data received from utility providers, one or more distributed energy generation systems 424, from an energy storage 427, and/or from other sources. The demand response layer 414 may receive inputs from other layers of the BMS controller 12 (e.g., the building subsystem integration layer 420, the integrated control layer 418, etc.). The inputs received from other layers may include environmental or sensor inputs such as temperature, carbon dioxide levels, relative humidity levels, air quality sensor outputs, occupancy sensor outputs, room schedules, and the like. The inputs may also include inputs such as electrical use (e.g., expressed in kWh), thermal load measurements, pricing information, projected pricing, smoothed pricing, curtailment signals from utilities, and the like.

According to some embodiments, the demand response layer 414 includes control logic for responding to the data and signals it receives. The responses can include communicating with the control algorithms in the integrated control layer 418, changing control strategies, changing setpoints, or activating/deactivating building equipment or subsystems in a controlled manner. The demand response layer 414 may also include control logic configured to determine when to utilize stored energy. For example, the demand response layer 414 may determine to begin using energy from the energy storage 427 just prior to the beginning of a peak use time period.

In some embodiments, the demand response layer 414 may include a control module configured to actively initiate control actions (e.g., automatically changing setpoints) which minimize energy costs based on one or more inputs representative of or based on demand (e.g., price, a curtailment signal, a demand level, etc.). In some embodiments, the demand response layer 414 may be configured utilize equipment models to determine a desired and/or improved set of control actions. The equipment models may include, for example, thermodynamic models describing the inputs, outputs, and/or functions performed by various sets of building equipment. The equipment models may represent collections of building equipment (e.g., subplants, chiller arrays, etc.) and/or individual devices (e.g., individual chillers, heaters, pumps, etc.).

The demand response layer 414 may further include or draw upon one or more demand response policy definitions (e.g., databases, XML files, etc.). The policy definitions may be edited or adjusted by a user (e.g., via a graphical user interface) so that the control actions initiated in response to demand inputs may be tailored for the user's application, desired comfort level, particular building equipment, or based on other concerns. For example, the demand response policy definitions may specify which equipment can be turned on or off in response to particular demand inputs, how long a system or piece of equipment should be turned off, what set points can be changed, what the allowable set point adjustment range is, how long to hold a high demand set point before returning to a normally scheduled setpoint, how close to approach capacity limits, which equipment modes to utilize, the energy transfer rates (e.g., the maximum rate, an alarm rate, other rate boundary information, etc.) into and out of energy storage devices (e.g., thermal storage tanks, battery banks, etc.), when to dispatch on-site generation of energy (e.g., via fuel cells, a motor generator set, etc.), and so forth.

The integrated control layer 418 may be configured to utilize data input or output of the building subsystem integration layer 420 and/or the demand response later 414 to determine control decisions. Due to the subsystem integration provided by the building subsystem integration layer 420, the integrated control layer 418 may integrate control activities of the building subsystems 428 such that the building subsystems 428 operate as a single integrated system (e.g., supersystem, integrated system). In some embodiments, the integrated control layer 418 includes control logic that utilizes inputs and outputs from a plurality of building subsystems 428 to provide greater comfort and energy savings relative to the comfort and energy savings that separate subsystems would provide alone. For example, the integrated control layer 418 may be configured to use an input from a first subsystem to make an energy-saving control decision for a second subsystem. Results of these decisions may be communicated back to the building subsystem integration layer 420.

The integrated control layer 418 is shown to be logically below the demand response layer 414. The integrated control layer 418 may be configured to enhance the effectiveness of the demand response layer 414 by enabling the building subsystems 428 and their respective control loops to be controlled in coordination with the demand response layer 414. This configuration may advantageously reduce disruptive demand response behavior relative to conventional systems. For example, the integrated control layer 418 may be configured to ensure that a demand response-driven upward adjustment to a set point for chilled water temperature (or another component that directly or indirectly affects temperature) does not result in an increase in fan energy (or other energy used to cool a space) that would result in greater total building energy use than would be saved via operation of the chiller.

The integrated control layer 418 may be configured to provide feedback to the demand response layer 414, and in response the demand response layer 414 may verify that constraints (e.g., temperature, lighting levels, etc.) are properly maintained even while demanded load shedding is in progress. The constraints may also include set point or sensed boundaries relating to safety, equipment operating limits and performance, comfort, fire codes, electrical codes, energy codes, and the like. The integrated control layer 418 is also logically below the FFD layer 416 and the automated measurement and validation (AM&V) layer 412. The integrated control layer 418 may be configured to provide calculated inputs (e.g., aggregations) to these higher levels based on outputs from more than one building subsystem 428.

The AM&V layer 412 may be configured to verify that control strategies commanded by the integrated control layer 418 or the demand response layer 414 are functioning properly (e.g., using data aggregated by the AM&V layer 412, the integrated control layer 418, the building subsystem integration layer 420, the FDD layer 416, or otherwise). The calculations performed by the AM&V layer 412 may be based on building system energy models and/or equipment models for individual BMS devices or subsystems. For example, the AM&V layer 412 may compare a model-predicted output with an actual output from one or more of the building subsystems 428 to determine an accuracy of the model.

The fault detection and diagnostics (FDD) layer 416 may be configured to provide on-going fault detection for the building subsystems 428, building subsystem devices (i.e., building equipment), and/or control algorithms used by the demand response layer 414 and/or the integrated control layer 418. The FDD layer 416 may receive data inputs from the integrated control layer 418, directly from one or more building subsystems 428 or devices and/or from another data source. The FDD layer 416 may automatically diagnose and respond to detected faults, in some embodiments. The responses to detected or diagnosed faults can include providing an alert message to a user, a maintenance scheduling system, or a control algorithm configured to attempt to repair the fault or to work-around the fault.

The FDD layer 416 may be configured to output a specific identification of a faulty component or cause of a fault (e.g., loose damper linkage) using detailed subsystem inputs available at the building subsystem integration layer 420. In other exemplary embodiments, the FDD layer 416 may be configured to provide “fault” events to the integrated control layer 418 which executes control strategies and policies in response to received indications of fault events. According to some embodiments, the FDD layer 416 (or a policy executed by an integrated control engine or business rules engine) may shut-down systems or direct control activities around faulty devices or systems to reduce energy waste, extend equipment life, or assure proper control response.

The FDD layer 416 may be configured to store or access a variety of different system data stores (or data points for live data). The FDD layer 416 may use some content of the data stores to identify faults at the equipment level (e.g., specific chiller, specific AHU, specific terminal unit, etc.) and/or other content to identify faults at component or subsystem levels. For example, one or more of the building subsystems 428 may generate temporal (i.e., time-series) data indicating the performance of the BMS 11 and the various components thereof. The data generated by the building subsystems 428 may include measured or calculated values that exhibit statistical characteristics and provide information about how the corresponding system or process (e.g., a temperature control process, a flow control process, etc.) is performing in terms of error from one or more corresponding set points. These processes may be examined by the FDD layer 416 to expose when the system begins to degrade in performance and alert a user to repair the fault before it becomes more severe.

As mentioned above, present embodiments are directed to a circuit board (e.g., printed circuit board) configured to accommodate multiple embodiments (e.g., options) of an electronic component configured to perform a particular function. For example, the circuit board may be configured to selectively accommodate (e.g., support, electrically couple to, integrate with, selectively accommodate) different embodiments of an electronic components. That is, the circuit board is configured to receive, electrically couple to, and operate with a first embodiment of an electronic component, and the circuit board is also configured to receive, electrically couple to, and operate with a second embodiment of the electronic component instead of the first electronic component. Each electronic component embodiment (e.g., option) may have different physical dimensions, configurations, arrangements, and/or pinouts relative to other embodiments of the electronic component. As described further below, the circuit board is configured to accommodate (e.g., operate with) each of the different embodiments of the electronic component without involving the redesigning, rerouting, and retesting the circuit board. In other words, a common embodiment of the circuit board may be utilized with different embodiments of the electronic component.

It should be appreciated that the techniques described herein may be utilized with any system, subsystem, controller, or other component configured to utilize a circuit board. For example, the present techniques may be incorporated with circuit boards utilized with any of the systems, subsystems, and/or components described above with reference to FIGS. 2-4, such as the BMS controller 12, the processing circuit 134, equipment of the HVAC system 20, the window control system 22, the lighting system 24, the door access system 26, a sensor system, a motor system, and so forth. The following discussion describes the present techniques in the context of certain applications and implementations, but it should be understood that any of the systems described herein, as well as other systems, may utilize circuit boards with the features described herein.

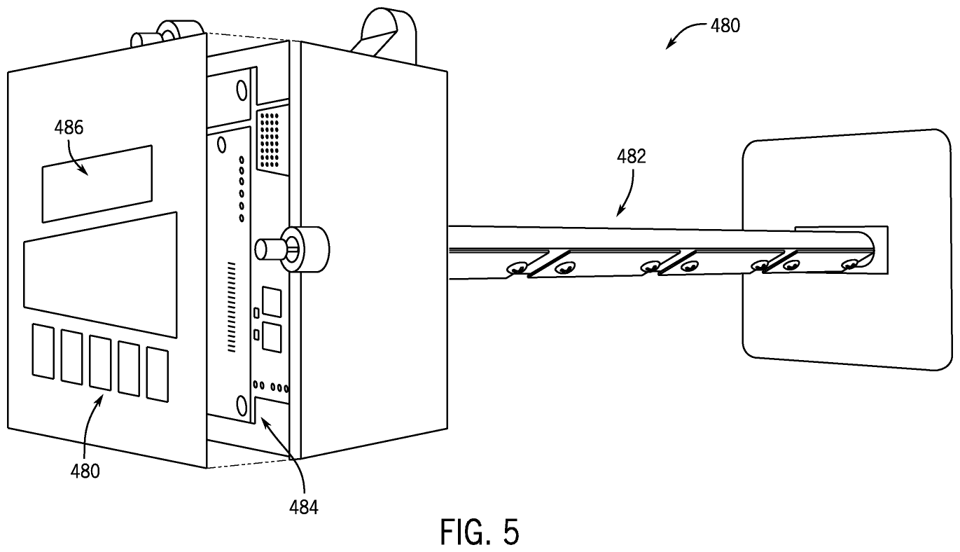

FIG. 5 is a perspective view of an embodiment of a sensor probe 480 (e.g., thermal dispersion airflow and temperature probe, sensor system, probe system) as an example of an electronic device utilizing the techniques disclosed herein. The sensor probe 480 may be utilized within the BMS 11 and/or a component or system of the BMS 11, such as the HVAC system 20, the AHU 32, and/or the VAV box 38 to measure thermal properties of one or more air flows. The sensor probe 480 includes a sensing element 482 (e.g., a sensor) configured to detect a property of an air flow and transduce property measurements into electrical signals. Additionally, the sensor probe 480 includes a circuit board 484 (e.g., printed circuit board) configured to perform a variety of functions, such as processing the electrical signals, controlling a display 486, processing user inputs (e.g., via buttons 488), and communicating with other devices (e.g., BMS controller 12, remote applications 18). As discussed in further detail below, the circuit board 484 includes features that enable selective integration of different embodiments of electrical components, which provides increased flexibility in manufacturing of the circuit board 484, as well as reduced costs and lead times associated with manufacturing.

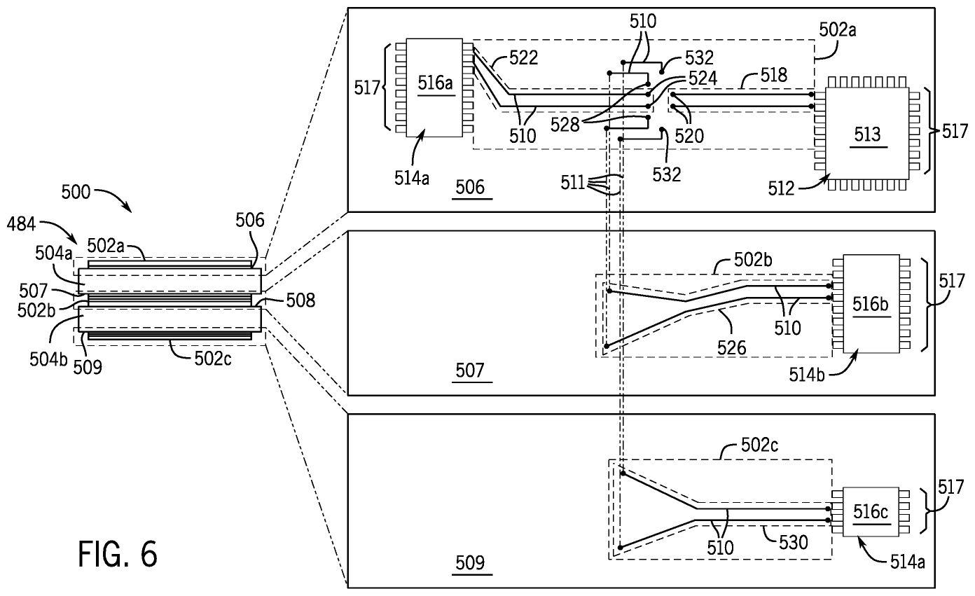

Referring now to FIG. 6, a schematic diagram of an embodiment of the circuit board 484 with alternate component integration capability is shown, in accordance with aspects of the present disclosure. The circuit board 484 may be included in an electronic apparatus or system. In an example, the circuit board 484 may be included in BMS devices, BMS systems, BMS subsystems, BMS controllers, or the like of embodiments of the BMS 11 described above with reference to FIGS. 2-4. As shown in FIG. 5, the circuit board 484 may be included in the sensor probe 480. The circuit board 484 may be a multi-layered printed circuit board (PCB). As a non-limiting example, the circuit board 484 is shown to include three layers of electronic traces separated by two layers of non-conductive material (e.g., substrates, insulating layers). The three layers of electronic traces include a first trace layer 502a, a second trace layer 502b, and a third trace layer 502c. Further, the two layers of non-conductive material include a first non-conductive layer 504a (e.g., first substrate) and a second non-conductive layer 504b (e.g., second substrate). The first non-conductive layer 504a includes first surface 506 (e.g., a top surface) and a second surface 507 (e.g., a bottom surface) oppose the first surface 506. The first trace layer 502a is formed on the first surface 506. The second non-conductive layer 504b also has two surfaces. Specifically, the second non-conductive layer 504b includes a third surface 508 (e.g., a top surface) and a fourth surface 509 (e.g., a bottom surface). The second trace layer 502b is disposed (e.g., sandwiched) between the second surface 507 and the third surface 508, and the third trace layer 502c is formed on the fourth surface 509. FIG. 6 illustrates the circuit board 484 in an initial configuration 500, whereby traces 510 (e.g., circuit traces, copper traces) are formed on the first surface 506, the second surface 507, the third surface 508, and/or the fourth surface 509, but no electronic components are mounted to the circuit board 484.

Each of the first trace layer 502a, the second trace layer 502b, and the third trace layer 502c may include one or more of the traces 510 printed, etched, electroplated, laminated, milled, or otherwise formed on the non-conductive layers 504a and 504b. The traces 510 function as conductive pathways to interconnect different components (e.g., electronic components) of the circuit board 484. Additionally, the circuit board 484 includes vias 511 (e.g., through holes, plated through holes, conductive through holes) extending through the non-conductive layers 504a and 504b to connect the first trace layer 502a to the second trace layer 502b and the third trace layer 502c.

Various electronic components may be mounted on the circuit board 484 to achieve a desired functionality. To implement different functionalities, different electronic components can be mounted on the circuit board 484. For example, electronic components mounted on an embodiment of the circuit board 484 for the lighting subsystem 442 may be different from electronic components mounted on an embodiment of the circuit board 484 for the fire safety subsystem 430. Similarly, electronic components utilized with an embodiment of the circuit board 484 for a mobile phone may be different from electronic components utilized with an embodiment of the circuit board 484 for a laptop. Examples of electronic components that can be mounted on the circuit board 484 may include resistors, capacitors, inductors, diodes, transistors, microcontrollers, microprocessors, integrated circuit (IC) chips, insulated-gate bipolar transistors (IGBTs), switches, sensors, and the like.

Electronic components that are functionally similar but manufactured by different original equipment manufacturers (OEMs) can have physical dissimilarities. For example, an analog to digital converter IC from two different OEMs may vary in terms of pinout, pin size, number of pins, packing dimensions, power requirements, supported communication protocol, and the like. In conventional circuit boards, if an electronic component configured to be utilized with a particular circuit board having a particular electronic trace layout becomes unavailable, further designing, routing, and testing is typically involved to produce a new circuit board designed to support and operate with a functionally similar but physically different alternate of the unavailable electronic component.

However, in accordance with the present disclosure, the traces 510, including the first trace layer 502a, the second trace layer 502b, and the third trace layer 502c, are formed on the circuit board 484 in a manner that provides the circuit board 484 with alternate component integration capability. In other words, the circuit board 484 may accommodate and operate with different embodiments of electronic components without redesigning, rerouting, and retesting of the circuit board 484. Therefore, if a specific make of an electronic component (e.g., IC chip) to be mounted on the circuit board 484 becomes unavailable, a functionally similar electronic component (e.g., IC chip) of a different make can be mounted on the circuit board 484 without changing the traces 510 on the circuit board 484. The multi-layer structure of the circuit board 484 is leveraged to achieve the alternate electronic component integration capability.

In a non-limiting example, the circuit board 484 may support a first electronic component 512 (e.g., a microcontroller, baseline electronic component, central electronic component, main electronic component, principal electronic component) and a second electronic component 514a (e.g., primary electronic component) to implement a desired functionality. The first electronic component 512 may be connected to the second electronic component 514a via the traces 510. In some instances, the second electronic component 514a may be unavailable (e.g., due to manufacturing shortages). In such instances, the second electronic component 514a may be substituted with one of a number of secondary electronic components (e.g., alternate component embodiments), such as a third electronic component 514b (e.g., first alternate electronic component) or a fourth electronic component 514c (e.g., second alternate electronic component). The second electronic component 514a may be similar in function to the third electronic component 514b and the fourth electronic component 514c. However, the electronic components 514a, 514b, and 514c may have differences that affect how they are mounted on and/or electrically coupled to the circuit board 484. For example, the differences may include variations in physical dimensions, pinouts, pin sizes, pin spacing, pin quantities, power requirements, working voltage, and the like. For example, the third electronic component 514b may have a different pinout configuration (e.g., pin arrangement) than the second electronic component 514a, and the fourth electronic component 514c may have a different number of pins from the second electronic component 514a.

The trace layers 502a, 502b, and 502c may be designed to selectively electrically couple the second electronic component 514a, third electronic component 514b, and fourth electronic component 514c, respectively, to the first electronic component 512. For example, the first electronic component 512 may correspond to a first footprint 513 on the circuit board 484. Additionally, the electronic components 514a, 514b, and 514c may correspond to a second footprint 516a, a third footprint 516b, and a fourth footprint 516c, respectively, on the circuit board 484. The trace layers 502a, 502b, and 502c may be configured to enable electrical coupling with the electronic components 514a, 514b, and 514c, respectively. The footprints 516a, 516b, and 516c are formed in designated spaces on the circuit board 484 to accommodate the particular space and pin requirements of the respective electronic components 514a, 514b, and 514c. Each footprint 516 may accommodate or include (e.g., extend along and/or contact) solder pads 517 and/or holes positioned and/or formed in specific locations on the circuit board 484 and may correspond to respective pins of each electronic component 514. Additionally, each footprint 516 may include an outline (e.g., courtyard, boundary, perimeter), text, and/or symbols on the circuit board 484 to facilitate installation by visually indicating the electronic component 514 corresponding to the footprint 516. In FIG. 6, the footprints 516 are shown in dotted lines to indicate mounting locations for the first electronic component 512, the second electronic component 514a, the third electronic component 514b, and the fourth electronic component 514c.

The first trace layer 502a on the first surface 506 has a first trace segment 518 designed and formed in accordance with one or more physical attributes of the first electronic component 512. The physical attributes may include a dimensional footprint, a pin layout, pin sizes, a number of pins, power requirements, supported communication protocol, or the like. The first trace segment 518 (e.g., trace segments) is electrically connected to jumper terminals 520 and may also be electrically connected to a socket configured to accept and receive (e.g., couple to) the first electronic component 512. The first trace layer 502a further includes a second trace segment 522 designed and formed in accordance with physical attributes of the second electronic component 514a. The second trace segment 522 is electrically connected with jumper terminals 524 and may also be electrically connected to a socket configured to accept and receive (e.g., couple to) the second electronic component 514a.

The second trace layer 502b, between the second surface 507 and the third surface 508, has a third trace segment 526 designed and formed in accordance with the physical attributes of the third electronic component 514b. The third trace segment 526 is electrically connected to jumper terminals 528 on the first surface 506 and may also be electrically connected to a socket configured to accept and receive (e.g., couple to) the third electronic component 514b. The third trace segment 526 may be electrically connected to the jumper terminals 528 through the first non-conductive layer 504a via the vias 511.

The third trace layer 502c on the fourth surface 509 has a fourth trace segment 530 designed and formed in accordance with the physical attributes of the fourth electronic component 514c. The fourth trace segment 530 is electrically connected to jumper terminals 532 on the first surface 506 and may also be electrically connected to a socket configured to accept and receive (e.g., couple to) the fourth electronic component 514c. The fourth trace segment 530 may be electrically connected to the jumper terminals 532 through the second non-conductive layer 504b via the vias 511.

Prior to component mounting, the jumper terminals 520 may not be electrically connected to any of the jumper terminals 524, 528, and 532. Therefore, in FIG. 6, the first trace segment 518 is not electrically connected to any of the second trace segment 522, the third trace segment 526, and the fourth trace segment 530. Fabrication of the circuit board 484 is followed by a component assembly process (e.g., component mounting).

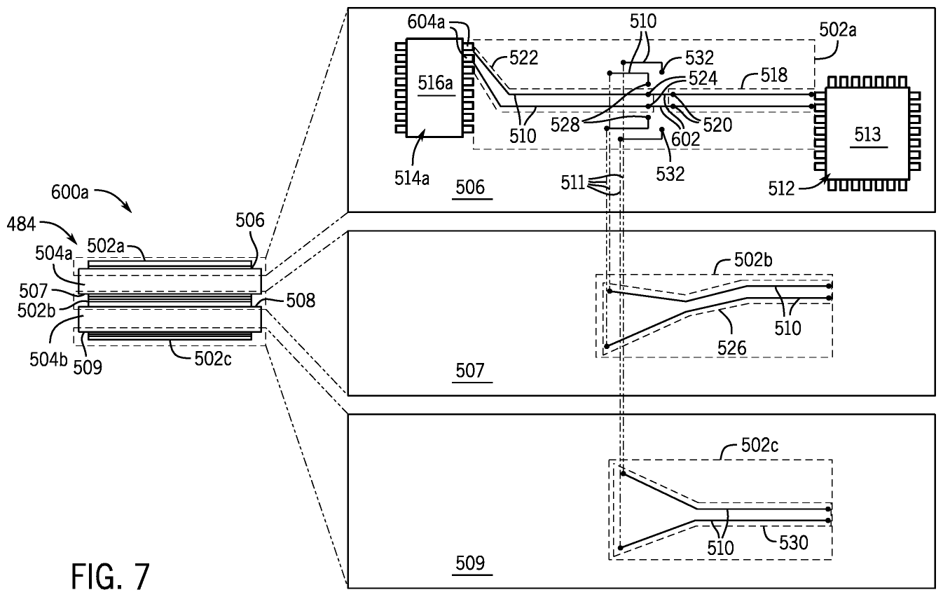

Each footprint 516 may be positioned to align with ends of a respect trace segment of the trace segments 518, 522, 526, and 530. For example, the second trace segment 522 may extend from the jumper terminals 528 to the appropriate solder pads 517 of the second footprint 516a. During component mounting, one of the second trace segment 522, the third trace segment 526, and the fourth trace segment 530 may be utilized to electrically connect the electronic component with which it is associated to the first trace segment 518 and thus the first electronic component 512. The remaining two trace segments may remain unused after the particular electronic component 514a, 514b, or 514c is mounted to the circuit board 484. The decision to select one of the second trace segment 522, the third trace segment 526, and the fourth trace segment 530 for use may be based on one or more constraints related to the second electronic component 514a, the third electronic component 514b, and the fourth electronic component 514c. The one or more constraints may include, but are not limited to, availability, cost, and/or performance, of the second electronic component 514a, the third electronic component 514b, and the fourth electronic component 514c. For example, when the second electronic component 514a (e.g., primary electronic component) is unavailable, and the third and fourth electronic components 514b and 514c (e.g., first and second secondary electronic components) are available for use, the second trace segment 522 formed in accordance with the second electronic component 514a may not be selected for use. Further, depending upon which of the third and fourth electronic components 514b and 514c (e.g., first and second alternate electronic components) is more cost effective, is more readily available, and/or has better performance, the corresponding trace segment may be selected for installation during component mounting. Exemplary scenarios describing the selection of one of the second trace segment 522, the third trace segment 526, and the fourth trace segment 530 according to different constraints are described below with reference to FIGS. 7-9.

FIG. 7 is a schematic diagram of an embodiment of a first configuration 600a of the circuit board 484, in which the second electronic component 514a (e.g., primary electronic component) is installed in its corresponding footprint 516a. In an assembly stage of the manufacturing process for the circuit board 484, a set of jumpers 602 may be installed to electrically connect the second trace segment 522 to the first trace segment 518. For example, the jumpers 602 may be wires, solder, or additional tracing added to the first trace layer 502a during the assembly stage. The jumpers 602 may extend between the jumper terminals 524 and 520. In one scenario, the second electronic component 514a may be available, and hence the second trace segment 522 (also referred to as “primary trace segment 522”) is selected for component mounting. In such a scenario, the third trace segment 526 (also referred to as “a secondary trace segment 526”) and the fourth trace segment 530 (also referred to as “another secondary trace segment 530”) remain unselected or unutilized for component mounting. That is, the third trace segment 526 and the fourth trace segment may not be electrically connected to the first trace segment 518.

In other embodiments, each of the second trace segment 522, the third trace segment 526, and the fourth trace segment 530 may be connected to the first trace segment 518 by default in the initial configuration 500. For example, in the initial configuration 500, the jumpers may electrically connect each of the jumper terminals 524, 528, and 532 to the jumper terminals 520. Then, in the assembly stage, the jumpers 602 electrically connecting the unselected trace segments (e.g., the third trace segment 526 and the fourth trace segment 530 in the first configuration 600a) may be disconnected (e.g., cut, severed, removed).

Upon selection of the second trace segment 522 (e.g., connection between the second trace segment 522 and the first trace segment 518), the second electronic component 514a may be mounted on the corresponding second footprint 516a. One or more pins 604a of the mounted second electronic component 514a configured for communication with the first electronic component 512 may be connected to the second trace segment 522. Further, the jumper terminals 520 may be electrically connected to the jumper terminals 524 (e.g., via solder) while the jumper terminals 528 and 532 remain open circuited or electrically disconnected. Upon connecting the jumper terminals 520 and 524, the first trace segment 518 may be electrically connected to the second trace segment 522, which in turn electrically connects the first electronic component 512 to the second electronic component 514a. Since the second trace segment 522 is used instead of the third trace segment 526 and the fourth trace segment 530 for component mounting, the third and fourth electronic components 514b and 514c may not be installed with the circuit board 484. Therefore, after the component mounting process, the third trace segment 526 and the fourth trace segment 530 may remain unused.

The circuit board 484, once assembled, may be used in an apparatus, such as a BMS device, a BMS system, a BMS subsystem, a BMS controller, or the like of the BMS 11 descried above. Although the application of the circuit board 484 is described with reference to the BMS 11, the circuit board 484 is not limited to utilization in the BMS 11 and can be used in any other suitable apparatus incorporating the circuit board 484.

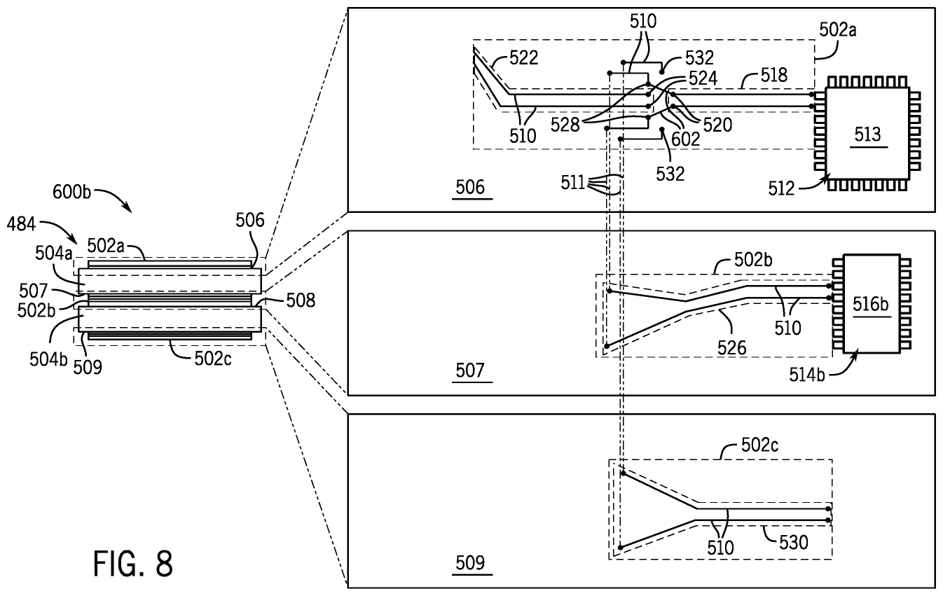

FIG. 8 is a schematic diagram of an embodiment of the circuit board 484 in a second configuration 600b, in which the third electronic component 514b (e.g., secondary electronic component, first alternate component embodiment) is installed in its corresponding footprint 516b. In the assembly stage of the manufacturing process for the circuit board 484, the jumpers 602 may be installed to electrically connect the third trace segment 526 to the first trace segment 518. For example, the jumpers 602 may be wires, solder, or additional tracing added to the first trace layer 502a during the assembly stage. The jumpers 602 may extend between the jumper terminals 528 and 520. In some instances, the second electronic component 514a and/or the fourth electronic component 514c may be unavailable or undesirable for use with the circuit board 484. Thus, the third trace segment 526 (also referred to as “secondary trace segment 526”) may be selected for component mounting. In such instances, the second trace segment 522 and the fourth trace segment 530 remain unselected and utilized for component mounting. That is, the second trace segment 522 and the fourth trace segment may not be electrically connected to the first trace segment 518.

Upon selection of the third trace segment 526 (e.g., connection between the third trace segment 526 and the first trace segment 518), the third electronic component 514b may be mounted on the corresponding third footprint 516b. One or more pins 604b of the mounted third electronic component 514b configured for communication with the first electronic component 512 may be electrically connected to the third trace segment 526. Further, the jumper terminals 520 may be electrically connected to the jumper terminals 528 (e.g., via solder) while the jumper terminals 524 and 532 remain open circuited or electrically disconnected. Upon electrically connecting the jumper terminals 520 and 528, the first trace segment 518 may be electrically connected to the third trace segment 526, which in turn electrically connects the first electronic component 512 to the third electronic component 514b. Since the third trace segment 526 is used instead of the second trace segment 522 and the fourth trace segment 530 for component mounting, the second and fourth electronic components 514a and 514c may not be installed with the circuit board 484. Therefore, after the component mounting process, the second trace segment 522 and the fourth trace segment 530 may remain unused.

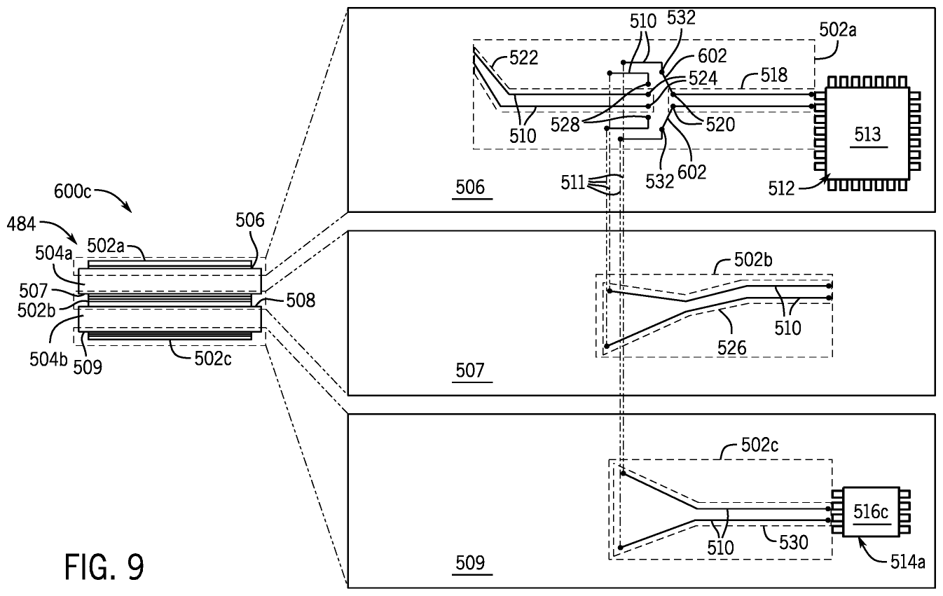

FIG. 9 is a schematic diagram of an embodiment of the circuit board 484, illustrating a third configuration 600c, whereby the fourth electronic component 514c (e.g., tertiary electronic component, second alternate component option) is installed in its corresponding footprint 516c. In the assembly stage of the manufacturing process for the circuit board 484, the jumpers 602 may be installed to electrically connect the fourth trace segment 530 to the first trace segment 518. For example, the jumpers 602 may be wires, solder, or additional tracing added to the first trace layer 502a during the assembly stage. The jumpers 602 may extend between the jumper terminals 532 and 520. In some instances, the second electronic component 514a and/or the third electronic component 514b may be unavailable or undesirable. Thus, the fourth trace segment 530 (also referred to as “secondary trace segment 530”) may be selected for component mounting. In such instances, the second trace segment 522 and the third trace segment 526 remain unselected for component mounting. That is, the second trace segment 522 and the third trace segment 526 may not be electrically connected to the first trace segment 518.

Upon selection of the fourth trace segment 530 (e.g., connection between the fourth trace segment 530 and the first trace segment 518), the fourth electronic component 514c may be mounted on the corresponding fourth footprint 516c. One or more pins 604c of the mounted fourth electronic component 514c configured for communication with the first electronic component 512 may be electrically connected to the fourth trace segment 530. Further, the jumper terminals 520 may be electrically connected to the jumper terminals 532 (e.g., via solder) while the jumper terminals 524 and 528 remain open circuited or electrically disconnected. Upon electrically connecting the jumper terminals 520 and 532, the first trace segment 518 may be electrically connected to the fourth trace segment 530, which in turn electrically connects the first electronic component 512 to the fourth electronic component 514c. Since the fourth trace segment 530 is used instead of the second trace segment 522 and the third trace segment 526 for component mounting, the second and third electronic components 514a and 514b may not be installed. Therefore, after the component mounting process, the second trace segment 522 and the third trace segment 526 may remain unused.

It should be appreciated to a person of ordinary skill in the art that the component mounting process is not limited to mounting the first electronic component 512 and any one of the second electronic component 514a, the third electronic component 514b, and the fourth electronic component 514c on the circuit board 484. In an actual implementation, many additional components may be mounted on the circuit board 484. Therefore, the circuit board 484 may further include additional trace segments formed thereon for other electronic components and corresponding assembly variants to support alternate component integration for the other electronic components as well. It should be understood by a person skilled in the art that, though the circuit board 484 is shown to support alternate component integration for the second electronic component 514a, the scope of the disclosure is not limited in this regard. In other words, a circuit board prepared in accordance with the present disclosure can support alternate component integration for as many electronic components as to be utilized in the same manner as the circuit board 484 supports integration of the assembly variants (e.g., the third electronic component 514b and the fourth electronic component 514c) of the second electronic component 514a.

Although the circuit board 484 is shown to include separate placement or mounting positions for the second electronic component 514a, the third electronic component 514b, and the fourth electronic component 514c, the scope of the disclosure is not limited in this regard. In some embodiments, a circuit board prepared in accordance with the present disclosure may have a single placement position for a primary electronic component embodiment and alternate embodiments thereof while having a primary trace segment for the primary electronic component and secondary trace segments for the alternates formed on different layers of the circuit board.

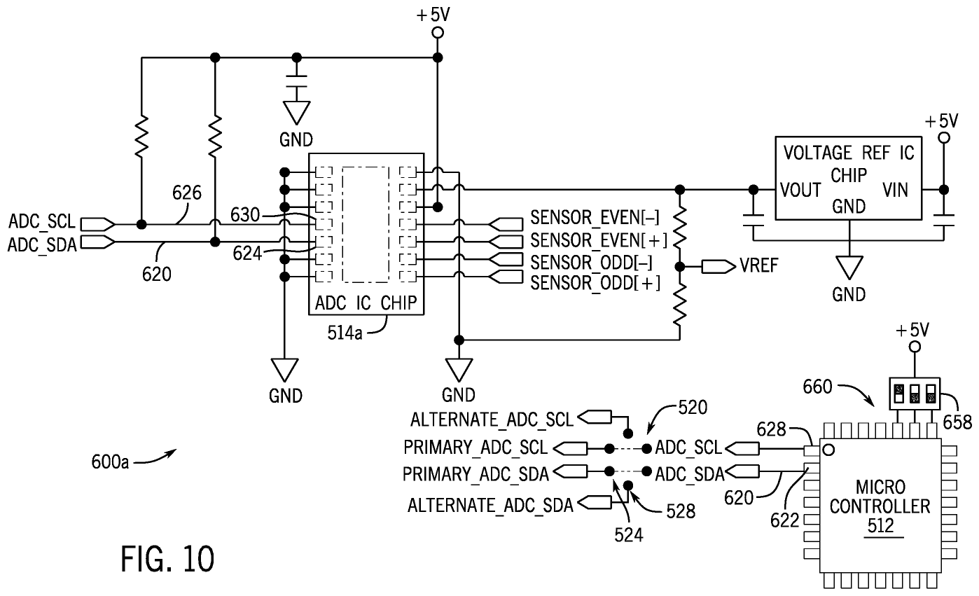

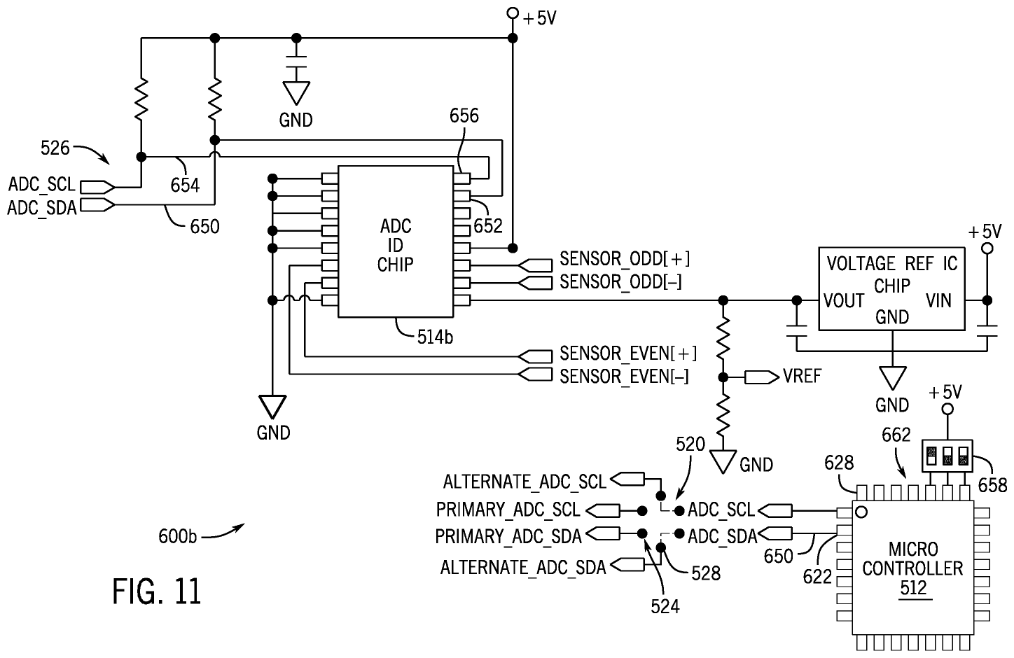

In some embodiments, arrangement of other electronic components on the circuit board 484 may depend on the selection of one of the second electronic component 514a, the third electronic component 514b, and the fourth electronic component 514c. In such implementations, trace segments supporting different arrangements of other electronic components may also be formed on the circuit board 484 without deviating from the techniques described herein. An example of such varying arrangement of other electronic components is shown in conjunction with FIGS. 10 and 11.

FIG. 10 is a schematic diagram of a portion of an embodiment of the circuit board 484 in the first configuration 600a. That is, the illustrated embodiment includes the first electronic component 512 and the second electronic component 514a. For example, the first electronic component 512 may be a microcontroller, and the second electronic component 514a may be a primary (e.g., first embodiment) analog-to-digital converter (ADC) IC chip. Communication between the first electronic component 512 and the second electronic component 514a may include a data line 620 (e.g., serial data line, first line; labeled “ADC_SDA”) extending between a first pin 622 of the first electronic component 512 and a first pin 624 of the second electronic component 514a. Additionally, the communication may include a clock line 626 (e.g., serial clock line, second line; labeled “ADC_SCL”) extending between a second pin 628 of the first electronic component 512 and a second pin 630 of the second electronic component 514a. The data line 620 and the clock line 626, as well as any other suitable lines of communication, may be transmitted via the first trace segment 518 and the second trace segment 522. The second trace segment 522 may electrically connect the first pin 624 and the second pin 630 of the second electronic component 514a to the jumper terminals 524. The jumper terminals 524 may be electrically connected to the jumper terminals 520 via the jumpers 602 (e.g., jumper wires, solder). The first trace segment 518 may electrically connect the jumper terminals 520 to the first pin 622 and the second pin 628 of the first electronic component 512. Thus, communication between the first electronic component 512 and the second electronic component 514a may be established.

FIG. 11 is a schematic diagram of a portion of an embodiment of the circuit board 484 in the second configuration 600b. That is, the illustrated embodiment includes the first electronic component 512 and the third electronic component 514b. For example, the first electronic component 512 may be a microcontroller, and the third electronic component 514b may be an alternate (e.g., second embodiment) analog-to-digital converter (ADC) IC chip having a different pinout and/or dimensions than the second electronic component 514a. Communication between the first electronic component 512 and the third electronic component 514b may include a data line 650 (e.g., serial data line, first line; labeled “ADC_SDA”) extending between the first pin 622 of the first electronic component 512 and a first pin 652 of the third electronic component 514b. Additionally, the communication may include a clock line 654 (e.g., serial clock line, second line; labeled “ADC_SCL”) extending between the second pin 628 of the first electronic component 512 and a second pin 656 of the third electronic component 514b. The data line 650 and the clock line 654, as well as any other suitable lines of communication, may be transmitted via the first trace segment 518 and the third trace segment 526. The third trace segment 526 may electrically connect the first pin 652 and the second pin 656 of the third electronic component 514b to corresponding vias 511 extending from the third trace segment 526, through the first non-conductive layer 504a, and to the jumper terminals 528. The jumper terminals 528 may be electrically connected to the jumper terminals 520 via the jumpers 602 (e.g., jumper wires, solder). The first trace segment 518 may connect the jumper terminals 520 to the first pin 622 and the second pin 628 of the first electronic component 512. Thus, communication between the first electronic component 512 and the third electronic component 514b may be established.

The circuit board 484 may also be configured to select an operating mode of the first electronic component 512 that corresponds to the configuration of the circuit board 484 (e.g., the first configuration 600a, the second configuration 600b). In an embodiment, the circuit board 484 may include a selection switch 658 (e.g., dip switch, rotary selection switch) configured to provide input to the first electronic component 512 indicative of an operating mode selected from a set of operating modes. The set of operating modes may include a first operating mode 660 corresponding to the first configuration 600a, a second operating mode 662 corresponding to the second configuration 600b, and a third operating mode corresponding to the third configuration 600c. The selection switch 658 may be set or configured during the manufacturing process (e.g., in the assembly stage) to select the operating mode for the first electronic component 512. The first electronic component 512 operating in a particular operating mode may utilize a corresponding communication protocol, processing logic, power setting, and the like based on the operating mode set by the selection switch 658. In FIG. 10, the selection switch 658 is set to the first operating mode 660. In FIG. 11, the selection switch 658 is set to the second operating mode 662.

In another embodiment, the first electronic component 512 may determine a suitable operating mode based on input signals received from the second electronic component 514a or the third electronic component 514b (e.g., via the first pin 622 and the second pin 628 of the first electronic component 512) electrically connected (e.g., mounted) to the circuit board 484. For example, in the first configuration 600a, the first electronic component 512 may receive a first identification signal from the second electronic component 514a indicative of the first configuration 600a. In response, the first electronic component 512 may determine to operate in the first operating mode 660 corresponding to the first configuration 600a. In the second configuration 600b, the first electronic component 512 may receive a second identification signal from the third electronic component 514b indicative of the second configuration 600b. In response, the first electronic component 512 may determine to operate in the second operating mode 662 corresponding to the second configuration 600b. In this way, the first electronic component 512 may determine the configuration of the circuit board 484 based on signals received at certain pin(s) (e.g., the first pin 622 and/or the second pin 628). Then, operation of the first electronic component 512 may be adjusted accordingly.

The techniques described above with reference to FIGS. 10 and 11 may be applied to the third configuration 600c using the fourth electrical component 514c. In fact, these techniques may be applied in embodiments of the circuit board 484 having more than three alternate component options on more than three trace layers. For example, the circuit board 484 may be configurable in a fourth, fifth, tenth, twentieth, and/or other numbered configuration, each corresponding to different alternate component options. As such, the present disclosure is not limited by the number of alternate component options illustrated in these figures.

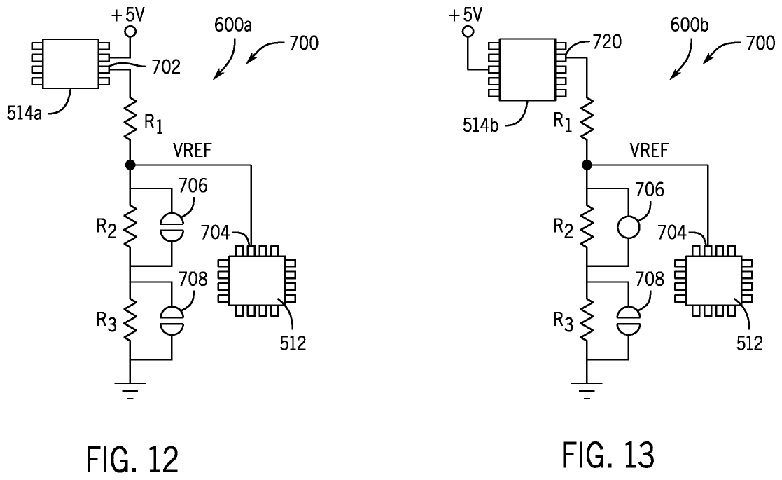

In another embodiment, the operating mode may be selected based on a reference voltage measured at a location on the circuit board 484. FIG. 12 is a schematic diagram of an embodiment of a voltage divider circuit 700 configured to select and detect a reference voltage indicative of the first configuration 600a. The voltage divider circuit 700 may be a passive linear circuit configured to receive an input voltage from a reference pin 702 of the second electronic component 514a and produce the reference voltage as an output to a pin 704 of the first electronic component 512. In some embodiments, each trace layer 502 may include a voltage divider circuit specifically routed to measure the reference voltage based on the electronic component 514 on the corresponding trace layer 502. In other embodiments, each trace layer 502 may route a reference voltage line from a respective footprint 516 to a single voltage divider circuit 700. The single voltage divider circuit 700 may be formed in the first trace layer 502a.

The voltage divider circuit 700 may include at least two impedances, such as resistors R1, R2, and R3, connected in series with the input voltage from the pin 702 of the second electronic component 514a. The reference voltage may be monitored (e.g., read by pin 704) at any suitable point along the series of resistors. As illustrated, the reference voltage is measured as the voltage drop across R2 and R3. In other embodiments, the reference voltage may be measured as a voltage drop across a different element or combination of elements. For example, the reference voltage may be measured at a point between the R2 and R3, such that the reference voltage corresponds to the voltage drop across R3 alone. In the first configuration 600a, the first electronic component 512 may measure the reference voltage at pin 704 and determine that the reference voltage corresponds to a value pre-associated with the first operating mode 660. Then, the first electronic component 512 may operate in the first operating mode 660 based on the reference voltage.

The voltage divider circuit 700 may include one or more conductive bridge footprints (e.g., solder bridge footprints, jumper terminals) across any of the resistors R1, R2, and R3. In the illustrated embodiment, a first conductive bridge footprint 706 extends across R2, and a second conductive bridge footprint 708 extends across R3. Each of R2 and R3 can be short-circuited by bridging the first conductive bridge footprint 706 and the second conductive bridge footprint 708, respectively. Such a short-circuit would change the reference voltage. In the first configuration 600a, neither R2 nor R3 is short-circuited. As a result, the reference voltage has a first value corresponding to the first operating mode 660. In another embodiment, a second value may correspond to the first operating mode 660, and any of R1, R2, and R3 may be short-circuited in the first configuration 600a to produce a reference voltage having the second value.

FIG. 13 illustrates an embodiment of the voltage divider circuit 700 in the second configuration 600b. Hence, the third electronic component 514b is installed on the circuit board 484. In the second configuration 600b, the voltage divider circuit 700 receives an input voltage from a reference voltage pin 720 of the third electronic component 514b. Again, the voltage divider circuit 700 produces an output voltage as the reference voltage detected by the first electronic component 512 at pin 704. In the second configuration 600b, one or more of the resistors may be short-circuited by bridging the first conductive bridge footprint 706 and/or the second conductive bridge footprint 708. For example, the first conductive bridge footprint 706 may be a solder bridge footprint. In the second configuration 600b, solder may be applied to the first conductive bridge footprint 706 to short-circuit R2 such that the combined voltage drop across R2 and R3 is reduced. Since the reference voltage is based on the voltage drop across R2 and R3, the first electronic component 512 receives a second value of the reference voltage different from the first value discussed above with respect to the first configuration 600a. The second value may be pre-associated with the second operating mode 662. Thus, the first electronic component 512 may select the second operating mode 662 based on determining that the reference voltage detected at pin 704 corresponds to the second value associated with the second operating mode 662.

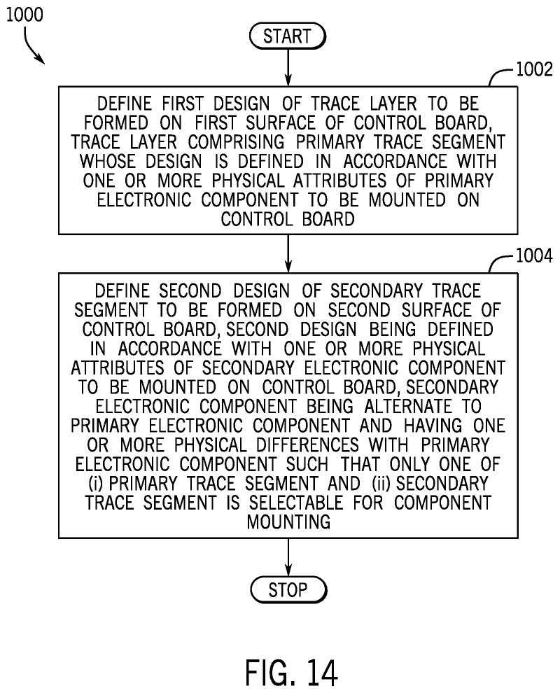

Referring now to FIG. 14, a flowchart 1000 illustrates an embodiment of a method to design a circuit board with alternate component integration capability is shown, according to an embodiment of the present disclosure. At 1002, a first design of a trace layer to be formed on a first surface (e.g., the first surface 506) of the circuit board (e.g., circuit board 484) is defined. The first design (e.g., a design of the first trace layer 502a) may be defined via a designing tool. The trace layer includes a primary trace segment (e.g., the second trace segment 522) whose design is defined in accordance with one or more physical attributes of a primary electronic component (for example, the second electronic component 514a) to be mounted on the circuit board. At 1004, a second design of a secondary trace segment to be formed on a second surface of the circuit board is defined. The second design (e.g., designs of the third and fourth trace segments 526 and 530) may be defined via a designing tool. The second design is defined in accordance with one or more physical attributes of a secondary electronic component (e.g., the third or fourth electronic components 514b or 514c) to be mounted on the circuit board. The secondary electronic component is an alternate to the primary electronic component and has one or more physical differences with the primary electronic component. One of the primary trace segment or the secondary trace segment may be selected for component mounting.

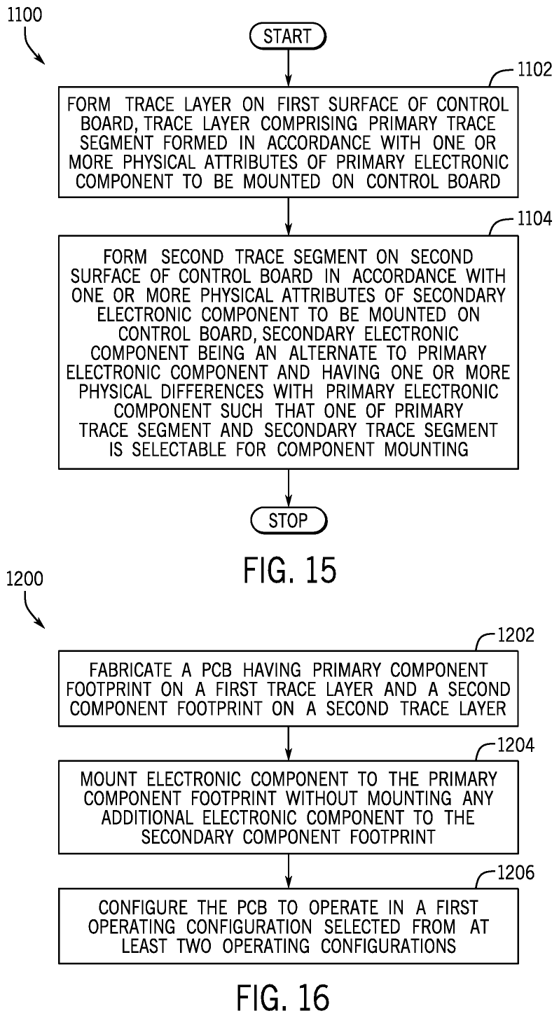

Referring now to FIG. 15, a flowchart 1100 illustrating an embodiment of a method to prepare a circuit board with alternate component integration capability is shown, according to an embodiment of the present disclosure. At 1102, a trace layer (e.g., the first trace layer 502a) is formed on a first surface (e.g., the first surface 506) of the circuit board (for example, the circuit board 484). The trace layer includes a primary trace segment (e.g., the second trace segment 522) that is formed in accordance with one or more physical attributes of a primary electronic component (e.g., the second electronic component 514a) to be mounted on the circuit board. At 1104, a secondary trace segment (e.g., the third and fourth trace segments 526 and 530) is formed on a second surface (e.g., the second surface 507 or the third surface 508) of the circuit board in accordance with one or more physical attributes of a secondary electronic component (e.g., the third and fourth electronic components 514b and 514c) to be mounted on the circuit board. The secondary electronic component is an alternate to the primary electronic component and has one or more physical differences with the primary electronic component. One of the primary trace segment or the secondary trace segment may be selected for component mounting.

FIG. 16 is a flowchart of an embodiment of a method 1200 of manufacturing a circuit board in accordance with the techniques discussed herein. At step 1202, during a fabrication stage, a circuit board (e.g., PCB) having a primary component footprint (e.g., second footprint 516a) on a first trace layer (e.g., 502a) and a secondary component footprint (e.g., third footprint 516b) on a second trace layer (e.g., 502b) may be fabricated. For example, raw board material (e.g., PCB substrate) may be cut to size, holes may be drilled in the board material, chemical films and/or laminates may be applied to the board material, and/or electrical trace may be etched or printed on the board material. The fabrication stage may produce a circuit board template ready for assembly with electronic components.

At step 1204, during an assembly stage, an electronic component (e.g., second electronic component 514a) may be mounted to the primary component footprint without mounting an additional electronic component (e.g., third electronic component 514b) to the secondary component footprint. For example, a pick and place machine or a technician may place the electronic component onto the primary component footprint. A machine or a technician may solder the electronic component onto solder pads of the primary component footprint.

At step 1206, the circuit board may be configured to operate in a first operating configuration (e.g., first configuration 600a) selected from at least two operating configurations (e.g., 600a and 600b). The first operating configuration may correspond to utilization of the primary component footprint. The at least two operating configurations include a second operating configuration corresponding to utilization of the second component footprint. For example, a machine or technician may position a selection switch (e.g., dip switch) in a first position corresponding to the first operating configuration. Based on the position of the selection switch, a microcontroller of the circuit board may receive a signal indicative of the electronic component being installed. Then, the microcontroller may determine to operate in the first operating configuration.

While only certain features and embodiments have been illustrated and described, many modifications and changes may occur to those skilled in the art, such as variations in sizes, dimensions, structures, shapes and proportions of the various elements, values of parameters, such as temperatures and pressures, mounting arrangements, use of materials, colors, orientations, and so forth, without materially departing from the novel teachings and advantages of the subject matter recited in the claims. The order or sequence of any process or method steps may be varied or re-sequenced according to alternative embodiments. It is, therefore, to be understood that the appended claims are intended to cover all such modifications and changes as fall within the true spirit of the disclosure.

Furthermore, in an effort to provide a concise description of the exemplary embodiments, all features of an actual implementation may not have been described, such as those unrelated to the presently contemplated best mode, or those unrelated to enablement. It should be appreciated that in the development of any such actual implementation, as in any engineering or design project, numerous implementation specific decisions may be made. Such a development effort might be complex and time consuming, but would nevertheless be a routine undertaking of design, fabrication, and manufacture for those of ordinary skill having the benefit of this disclosure, without undue experimentation.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112 (f). However, for any claims containing elements designated in any other manner, it is intended that such elements are not to be interpreted under 35 U.S.C. 112 (f).

1. A circuit board, comprising:
a first non-conductive layer and a second non-conductive layer;
a first electronic component, wherein the circuit board is configurable to operate in a first configuration with a second electronic component, and the circuit board is configurable to operate in a second configuration with a third electronic component instead of the second electronic component;
a first trace layer disposed on the first non-conductive layer, wherein the first trace layer is configured to electrically couple the first electronic component to the second electronic component in the first configuration of the circuit board; and
a second trace layer disposed between the first non-conductive layer and the second non-conductive layer, wherein the second trace layer is configured to electrically couple the first electronic component to the third electronic component in the second configuration of the circuit board.

2. The circuit board of claim 1, wherein:
the circuit board is configurable to operate in a third configuration with a fourth electronic component instead of the second electronic component or the third electronic component,
the circuit board comprises a third trace layer disposed on the second non-conductive layer, and
the third trace layer is configured to electrically couple the first electronic component to the fourth electronic component in the third configuration of the circuit board.

3. The circuit board of claim 2, wherein the first non-conductive layer is disposed between the first trace layer and the second trace layer, and the second non-conductive layer is disposed between the second trace layer and the third trace layer.

4. The circuit board of claim 1, wherein:
the first non-conductive layer comprises a first surface and a second surface,
the second non-conductive layer comprises a third surface and a fourth surface,
the first trace layer is disposed on the first surface, and
the second trace layer is disposed between the second surface and the third surface.

5. The circuit board of claim 1, wherein the first electronic component is configured to communicate with the second electronic component via a first communication protocol in the first configuration, and the first electronic component is configured to communicate with the third electronic component via a second communication protocol in the second configuration.

6. The circuit board of claim 5, wherein the first electronic component is configured to utilize the first communication protocol or the second communication protocol based on respective signals received from the second electronic component and the third electronic component, respectively.

7. The circuit board of claim 5, comprising a dip switch communicatively coupled to the first electronic component, wherein the first electronic component is configured to utilize the first communication protocol or the second communication protocol based on a setting of the dip switch.

8. The circuit board of claim 1, wherein the first electronic component is configured to:
determine a reference voltage at a location on the circuit board; and
determine that the circuit board is configured to operate in the first configuration or the second configuration based on the reference voltage.

9. The circuit board of claim 8, wherein the first electronic component is configured to operate in a first operating mode in response to a determination that the circuit board is configured to operate in the first configuration; and
operate in a second operating mode in response to a determination that the circuit board is configured to operate in the second configuration.

10. The circuit board of claim 8, comprising a voltage divider configured to produce the reference voltage.

11. The circuit board of claim 10, wherein the voltage divider is configured to:
receive an input voltage from the second electronic component or the third electronic component; and
output the reference voltage to a reference voltage pin of the first electronic component.

12. The circuit board of claim 10, wherein:
the voltage divider comprises an impedance element and a conductive bridge configurable to short-circuit the impedance element, and
the reference voltage is adjustable by short-circuiting the impedance element via the conductive bridge.

13. The circuit board of claim 12, wherein the conductive bridge is a solder bridge.

14. The circuit board of claim 1, wherein:
the first trace layer comprises a first trace segment extending from a first footprint of the first electronic component,
the first trace layer comprises a second trace segment extending from a second footprint of the second electronic component,
the second trace layer comprises a third trace segment extending from a third footprint of the third electronic component, and
the circuit board comprises a via extending from the third trace segment to the first trace layer.

15. The circuit board of claim 1, wherein the first electronic component is a microcontroller.

16. A circuit board, comprising:
a microcontroller;
one of a primary electronic component or a secondary electronic component;
a first trace layer formed on a first surface of the circuit board, wherein the first surface comprises a primary component footprint corresponding to the primary electronic component; and
a second trace layer formed on a second surface of the circuit board, opposite the first surface, wherein:
the second surface comprises a secondary component footprint corresponding to the secondary electronic component,
the circuit board is configurable to operate in a first configuration associated with installation of the primary electronic component on the primary component footprint; and
the circuit board is configurable to operate in a second configuration associated with installation of the secondary electronic component on the secondary component footprint.

17. The circuit board of claim 16, wherein the microcontroller is configured to:
determine that the circuit board is in the first configuration; and
communicate with the primary electronic component using a first communication protocol in response to determining that the circuit board is in the first configuration.

18. The circuit board of claim 16, wherein:
the primary electronic component is an integrated circuit comprising a plurality of pins, and
the primary component footprint comprises a plurality of solder pads corresponding to the plurality of pins.

19. A method, comprising:
fabricating a printed circuit board (PCB) with a first trace layer disposed on a first surface of the PCB and a second trace layer disposed on a second surface of the PCB, wherein the first surface comprises a primary component footprint, and the second surface comprises a secondary component footprint;
mounting an electronic component to the primary component footprint without mounting an additional electronic component to the secondary component footprint; and
configuring the PCB to operate in a first operating configuration selected from at least two operating configurations, wherein the first operating configuration corresponds to utilization of the primary component footprint, and the at least two operating configurations include a second operating configuration corresponding to utilization of the secondary component footprint.

20. The method of claim 19, comprising configuring the PCB to operate in the first operating configuration by applying solder to a solder bridge footprint, wherein solder bridge footprint is formed on the first surface, the second surface, or a third surface of the PCB.
